(19) United States
(12) Patent Application Publication
(10) Pub. No.: US 2024/0304450 A1
(43) Pub. Date: Sep. 12, 2024

(54) ELECTRONIC PACKAGE STRUCTURE

(71) Applicant: Advanced Semiconductor Engineering, Inc., Kaohsiung (TW)

(72) Inventors: An-Hsuan HSU, Kaohsiung (TW); Chin-Li KAO, Kaohsiung (TW)

(73) Assignee: Advanced Semiconductor Engineering, Inc., Kaohsiung (TW)

(21) Appl. No.: 18/118,736

(22) Filed: Mar. 7, 2023

(51) Int. Cl. H01L 21/285; H01L 21/48; H01L 21/56; H01L 23/00; H01L 23/46; H05K 1/02

(52) U.S. Cl. CPC H01L 21/28506; H01L 21/4889; H01L 21/56; H01L 23/46; H01L 24/20; H05K 1/0296

(57) ABSTRACT

An electronic package structure includes a first electronic component, a first thermal conductive structure and a second thermal conductive structure. The first thermal conductive structure is disposed over the first electronic component. The second thermal conductive structure is disposed between the first electronic component and the first thermal conductive structure. A first heat transfer rate of the second thermal conductive structure along a first direction from the first electronic component to the first thermal conductive structure is greater than a second heat transfer rate of the second thermal conductive structure along a second direction nonparallel with the first direction from the first electronic component to an element other than the first thermal conductive structure.

### BACKGROUND

### 1. Field of the Disclosure

The present disclosure relates to an electronic package structure and a manufacturing method, and to an electronic package structure including an electronic component and a method for manufacturing the electronic package structure.

### 2. Description of the Related Art

During an operation of an electronic package structure, the heat generated by a semiconductor die or a semiconductor chip in the electronic package structure may adversely affect the performance of the electronic package structure. However, the semiconductor die or the semiconductor chip may be encapsulated in an encapsulant such as a molding compound with a relatively low thermal conductivity. Thus, a heat dissipation is a critical issue.

### SUMMARY

In some embodiments, an electronic package structure includes a first electronic component, a first thermal conductive structure and a second thermal conductive structure. The first thermal conductive structure is disposed over the first electronic component. The second thermal conductive structure is disposed between the first electronic component and the first thermal conductive structure. A first heat transfer rate of the second thermal conductive structure along a first direction from the first electronic component to the first thermal conductive structure is greater than a second heat transfer rate of the second thermal conductive structure along a second direction nonparallel with the first direction from the first electronic component to an element other than the first thermal conductive structure.

In some embodiments, an electronic package structure includes a first circuit pattern structure, an electronic component, a second circuit pattern structure and a plurality of wires. The electronic component is disposed over the first circuit pattern structure. The second circuit pattern structure is disposed over the electronic component. A gap is between the second circuit pattern structure and the electronic component. The gap includes a first portion and a second portion. A height of the first portion is different from a height of the second portion. The wires are disposed in the first portion and the second portion.

In some embodiments, an electronic package structure includes a first circuit pattern structure, an electronic component, a second circuit pattern structure, a re-flowable contactors and a fixing structure. The first circuit pattern structure includes a first pad. The electronic component is disposed over the first circuit pattern structure. The second circuit pattern structure is disposed over the electronic component, and includes a second pad facing the first pad. The re-flowable contactors are disposed between and electrically connect the first pad of the first circuit pattern structure and the second pad of the second circuit pattern structure. The fixing structure is disposed between the electronic component and the second circuit pattern structure, and is configured to inhibit shift between the second pad and the first pad during a reflow process.

### BRIEF DESCRIPTION OF THE DRAWINGS

Aspects of some embodiments of the present disclosure are readily understood from the following detailed description when read with the accompanying figures. It is noted that various structures may not be drawn to scale, and dimensions of the various structures may be arbitrarily increased or reduced for clarity of discussion.

FIG. 1 illustrates a cross-sectional view of an electronic package structure according to some embodiments of the present disclosure.

FIG. 2 illustrates an enlarged view of an area “A” of FIG. 1.

FIG. 3 illustrates an enlarged view of an area “B” of FIG. 2.

FIG. 4 illustrates a cross-sectional view of an example of a plurality of wires according to some embodiments of the present disclosure.

FIG. 5 illustrates a cross-sectional view of an example of a plurality of wires according to some embodiments of the present disclosure.

FIG. 5A illustrates a cross-sectional view of an example of a plurality of wires according to some embodiments of the present disclosure.

FIG. 5B illustrates a cross-sectional view of an example of a plurality of wires according to some embodiments of the present disclosure.

FIG. 5C illustrates a cross-sectional view of an example of a plurality of wires 4b according to some embodiments of the present disclosure.

FIG. 6 illustrates a cross-sectional view of an example of a plurality of wires according to some embodiments of the present disclosure.

FIG. 7 illustrates a cross-sectional view of an example of a plurality of wires according to some embodiments of the present disclosure.

FIG. 7A illustrates a cross-sectional view of an example of a plurality of wires according to some embodiments of the present disclosure.

FIG. 8 illustrates a structure of an enlarged view of an area of a cross-sectional view of an electronic package structure according to some embodiments of the present disclosure.

FIG. 8A illustrates a structure of an enlarged view of an area of a cross-sectional view of an electronic package structure according to some embodiments of the present disclosure.

FIG. 9 illustrates a structure of an enlarged view of an area of a cross-sectional view of an electronic package structure according to some embodiments of the present disclosure.

FIG. 10 illustrates a structure of an enlarged view of an area of a cross-sectional view of an electronic package structure according to some embodiments of the present disclosure.

FIG. 10A illustrates a structure of an enlarged view of an area of a cross-sectional view of an electronic package structure according to some embodiments of the present disclosure.

FIG. 11 illustrates a structure of an enlarged view of an area of a cross-sectional view of an electronic package structure according to some embodiments of the present disclosure.

FIG. 12 illustrates a cross-sectional view of an electronic package structure according to some embodiments of the present disclosure.

FIG. 13 illustrates an enlarged view of an area “C” of FIG. 12.

FIG. 14 illustrates a structure of an enlarged view of an area of a cross-sectional view of an electronic package structure according to some embodiments of the present disclosure.

FIG. 15 illustrates a cross-sectional view of an electronic package structure according to some embodiments of the present disclosure.

FIG. 16 illustrates a cross-sectional view of an electronic package structure according to some embodiments of the present disclosure.

FIG. 17 illustrates a cross-sectional view of an electronic package structure according to some embodiments of the present disclosure.

FIG. 17A illustrates an enlarged view of an area “C1” of FIG. 17.

FIG. 18 illustrates a cross-sectional view of an electronic package structure according to some embodiments of the present disclosure.

FIG. 19 illustrates a cross-sectional view of an electronic package structure according to some embodiments of the present disclosure.

FIG. 20 illustrates an enlarged view of an area “D” of FIG. 19.

FIG. 21 illustrates a cross-sectional view of an electronic package structure according to some embodiments of the present disclosure.

FIG. 22 illustrates an enlarged view of an area “E” of FIG. 21.

FIG. 22A illustrates a structure of an enlarged view of an area of a cross-sectional view of an electronic package structure according to some embodiments of the present disclosure.

FIG. 23 illustrates a cross-sectional view of an electronic package structure according to some embodiments of the present disclosure.

FIG. 24 illustrates a cross-sectional view of an electronic package structure according to some embodiments of the present disclosure.

FIG. 24A illustrates a cross-sectional view of an electronic package structure according to some embodiments of the present disclosure.

FIG. 25 illustrates an example of a top view of the electronic component of FIG. 1.

FIG. 26 illustrates an example of a top view of the electronic component of FIG. 1.

FIG. 26A illustrates an example of a top view of the electronic component of FIG. 1.

FIG. 26B illustrates an example of a top view of the electronic package structure of FIG. 24A, wherein the second electronic component is omitted.

FIG. 27 illustrates an example of a top view of the electronic component of FIG. 1.

FIG. 28 illustrates one or more stages of an example of a method for manufacturing an electronic package structure according to some embodiments of the present disclosure.

FIG. 29 illustrates one or more stages of an example of a method for manufacturing an electronic package structure according to some embodiments of the present disclosure.

FIG. 30 illustrates one or more stages of an example of a method for manufacturing an electronic package structure according to some embodiments of the present disclosure.

FIG. 31 illustrates one or more stages of an example of a method for manufacturing an electronic package structure according to some embodiments of the present disclosure.

FIG. 32 illustrates one or more stages of an example of a method for manufacturing an electronic package structure according to some embodiments of the present disclosure.

FIG. 33 illustrates one or more stages of an example of a method for manufacturing an electronic package structure according to some embodiments of the present disclosure.

FIG. 34 illustrates one or more stages of an example of a method for manufacturing an electronic package structure according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

The following disclosure provides many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

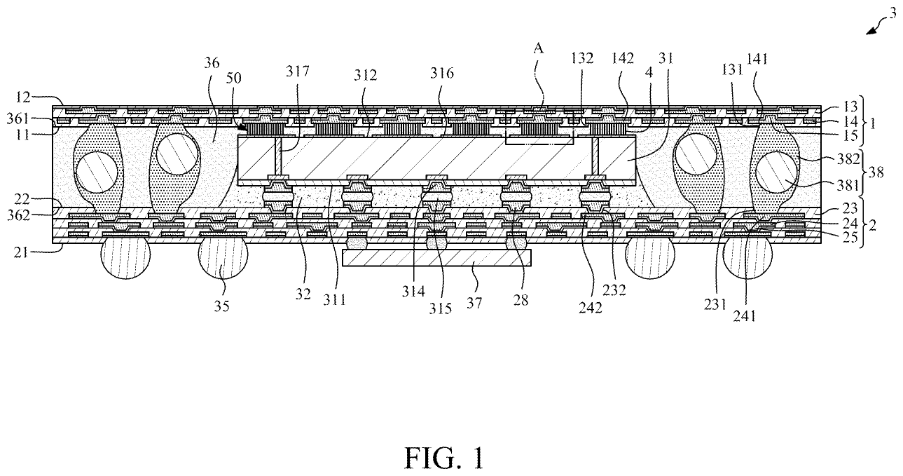

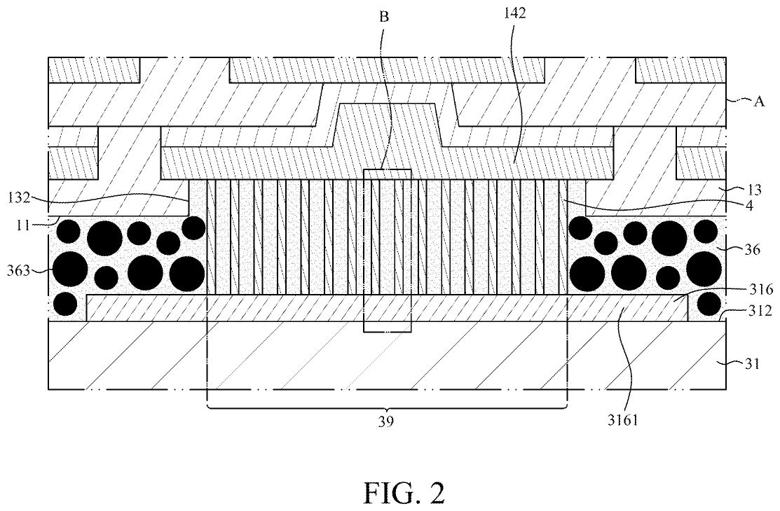

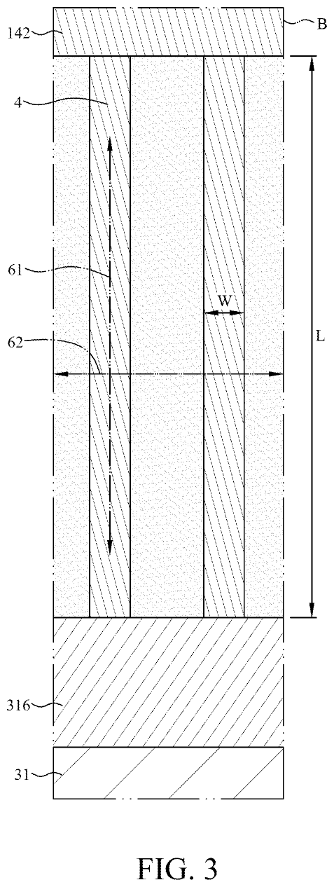

FIG. 1 illustrates a cross-sectional view of an electronic package structure 3 according to some embodiments of the present disclosure. FIG. 2 illustrates an enlarged view of an area “A” of FIG. 1. FIG. 3 illustrates an enlarged view of an area “B” of FIG. 2. The electronic package structure 3 may include an upper circuit pattern structure 1, a lower circuit pattern structure 2, an electronic component 31, a second thermal conductive structure 4, at least one electrical connector 38, an encapsulant 36, a capacitor 37 and a plurality of external connectors 35. The upper circuit pattern structure 1 may be also referred to as “a first thermal conductive structure 1.” The electronic component 31 may be also referred to as “a first electronic component 31.” The electrical connector 38 may be also referred to as “a re-flowable contactor 38.”

The upper circuit pattern structure 1 (e.g., the first thermal conductive structure) is disposed over the lower circuit pattern structure 2 and the electronic component 31. There may be a gap 50 between the electronic component 31 and the upper circuit pattern structure 1. The upper circuit pattern structure 1 may be physically connected and electrically connected to the lower circuit pattern structure 2 through the at least one electrical connector 38. The upper circuit pattern structure 1 may be a redistribution layer (RDL) structure, a wiring structure or a substrate structure, and may be disposed on a top surface 361 of the encapsulant 36. The upper circuit pattern structure 1 may have a first surface 11 (e.g., a bottom surface) and a second surface 12 (e.g., a top surface) opposite to the first surface 11. The upper circuit pattern structure 1 may include at least one dielectric layer 13, at least one circuit layer 14 (e.g., a patterned circuit layer or a redistribution layer) and at least one inner via 15. As shown in FIG. 1, the upper circuit pattern structure 1 may include three dielectric layers 13, two circuit layers 14 and a plurality of inner vias 15. However, the amount of the dielectric layers 13 and the amount of the circuit layers 14 are not limited in the present disclosure. The dielectric layer 13 may be made of a cured photoimageable dielectric (PID) material such as epoxy or polyimide (PI) including photoinitiators. The dielectric layers 13 may cover the circuit layers 14, and may be stacked on one another. The inner vias 15 may connect the circuit layers 14. The inner via 15 may taper upward. Thus, a width of the inner via 15 may decrease upward. The circuit layer 14 may include a seed layer and a conductive layer disposed thereon. In some embodiments, the seed layer may be omitted. A bottommost one of the circuit layers 14 may include at least one first outer bond pad 141 and at least one first inner bond pad 142 exposed from a bottommost one of the dielectric layers 13.

As shown in FIG. 1, the bottommost dielectric layer 13 may define at least one first opening 131 recessed from the first surface 11 (e.g., the bottom surface) of the upper circuit pattern structure 1 to expose the first outer bond pad 141, so that the electrical connector 38 may be physically connected and electrically connected to the first outer bond pad 141 of the bottommost circuit layer 14 through the first opening 131 of the bottommost dielectric layer 13. In addition, the bottommost dielectric layer 13 may further define at least one second opening 132 recessed from the first surface 11 (e.g., the bottom surface) of the upper circuit pattern structure 1 to expose the first inner bond pad 142, so that the wires 4 may be physically connected and thermally connected to the first inner bond pad 142 of the bottommost circuit layer 14 through the second opening 132 of the bottommost dielectric layer 13.

The lower circuit pattern structure 2 may be a redistribution layer (RDL) structure, a wiring structure or a substrate structure, and may be disposed on a bottom surface 362 of the encapsulant 36. The lower circuit pattern structure 2 may have a first surface 21 (e.g., a bottom surface) and a second surface 22 (e.g., a top surface) opposite to the first surface 21. The lower circuit pattern structure 2 may include at least one dielectric layer 23, at least one circuit layer 24 (or a redistribution layer), at least one inner via 25 and a plurality of protrusion pads 28. As shown in FIG. 1, the lower circuit pattern structure 2 may include four dielectric layers 23, three circuit layers 24 and a plurality of inner vias 25. However, the amount of the dielectric layers 23 and the amount of the circuit layers 24 are not limited in the present disclosure. The dielectric layer 23 may be made of a cured photoimageable dielectric (PID) material such as epoxy or polyimide (PI) including photoinitiators. The dielectric layers 23 may cover the circuit layers 24, and may be stacked on one another. The inner vias 25 may connect the circuit layers 24. The inner via 25 may taper downward. Thus, a width of the inner via 25 may decrease downward. A tapering direction of the inner via 25 of the lower circuit pattern structure 2 may be different from or opposite to a tapering direction of the inner via 15 of the upper circuit pattern structure 1. The circuit layer 24 may include a seed layer and a conductive layer disposed thereon. In some embodiments, the seed layer may be omitted. The topmost circuit layer 24 may include at least one second outer pad 241 and at least one second inner pad 242 exposed from a topmost one of the dielectric layers 23.

As shown in FIG. 1, the topmost dielectric layer 23 may define at least one first opening 231 recessed from the second surface 22 (e.g., the top surface) of the lower circuit pattern structure 2 to expose the second outer pad 241, so that the electrical connector 38 may be physically connected and electrically connected to the second outer pad 241 of the topmost circuit layer 24 through the first opening 231 of the topmost dielectric layer 23. In addition, the topmost dielectric layer 23 may further define at least one second opening 232 recessed from the second surface 22 (e.g., the top surface) of the lower circuit pattern structure 2 to expose the second inner pad 242, so that the protrusion pads 28 may be disposed in the second opening 232 and may electrically connect the second inner pad 242 of the topmost circuit layer 24. The protrusion pads 28 may protrude from the second surface 22 (e.g., the top surface) of the lower circuit pattern structure 2.

In some embodiments, the lower circuit pattern structure 2 may be also referred to as “a stacked structure” or “a high-density electronic structure” or “a high-density stacked structure.” The circuit layers 24 of the lower circuit pattern structure 2 may be also referred to as “a high-density redistribution layer.” The upper circuit pattern structure 1 may be also referred to as “a stacked structure” or “a low-density electronic structure” or “a low-density stacked structure.” The circuit layers 14 of the upper circuit pattern structure 1 may be also referred to as “a low-density redistribution layer.” However, in some embodiments, the lower circuit pattern structure 2 may be also referred to as “a low-density electronic structure” or “a low-density stacked structure.” The circuit layer 24 of the lower circuit pattern structure 2 may be also referred to as “a low-density redistribution layer.” The upper circuit pattern structure 1 may be also referred to as “a high-density electronic structure” or “a high-density stacked structure.” The circuit layer 14 of the upper circuit pattern structure 1 may be also referred to as “a high-density redistribution layer.” It is noted that a density of a circuit line (including, for example, a trace or a pad) of the high-density redistribution layer is greater than a density of a circuit line of a low-density redistribution layer. That is, the count of the circuit line (including, for example, a trace or a pad) in a unit area of the high-density redistribution layer is greater than the count of the circuit line in an equal unit area of the low-density redistribution layer, such as about 1.2 times or greater, about 1.5 times or greater, or about 2 times or greater, or about 5 times or greater. Alternatively, or in combination, a line width/line space (L/S) of the high-density redistribution layer is less than an L/S of the low-density redistribution layer, such as about 90% or less, about 50% or less, or about 20% or less.

The electronic component 31 may be disposed over the second surface 22 of the lower circuit pattern structure 2. The electronic component 31 may be bonded to the lower circuit pattern structure 2, and electrically connected to the circuit layer 24 of the lower circuit pattern structure 2. The electronic component 31 may be a semiconductor device such as an application specific integrated circuit (ASIC) die or a high bandwidth memory (HBM) die. The electronic component 31 may have a bottom surface 311 (e.g., an active surface), a top surface 312 (e.g., a backside surface) opposite to the bottom surface 311, and a lateral surface extending between the top surface 312 and the bottom surface 311. The electronic component 31 may include a seed layer 316, a plurality of electrical contacts 314 and at least one conductive via 317. The seed layer 316 may be disposed on the top surface 312 (e.g., the backside surface) of the electronic component 31. A material of the seed layer 316 may include titanium (Ti), copper (Cu) or an alloy thereof. The seed layer 316 may be patterned to form a plurality of pads 3161 (FIG. 2). Thus, the seed layer 316 may not occupy the entire top surface 312 (e.g., the backside surface) of the electronic component 31. The electrical contacts 314 may be disposed adjacent to the bottom surface 311 (e.g., the active surface). The electrical contacts 314 may be exposed or may protrude from the bottom surface 311 (e.g., the active surface) for electrical connection. The electrical contacts 314 may be pads, bumps, studs, pillars or posts. In some embodiments, the electrical contacts 314 of the electronic component 31 may be electrically connected and physically connected to the protrusion pads 28 of the lower circuit pattern structure 2 through a plurality of solder materials 315. In other words, the electronic component 31 may be electrically connected to the lower circuit pattern structure 2 by flip-chip bonding. The conductive via 317 may extend through the electronic component 31, and the seed layer 316 may be electrically connected to the electrical contacts 314 through the conductive via 317.

As shown in FIG. 1, the electronic component 31 may be disposed between the upper circuit pattern structure 1 and the lower circuit pattern structure 2. An underfill 32 may be further included, and may be disposed in the space between the electronic component 31 and the lower circuit pattern structure 2 so as to cover and protect the joints formed by the electrical contacts 314, the protrusion pads 28 and the solder materials 315. In some embodiments, the underfill 32 may be omitted.

The electrical connector 38 may be an interconnection structure. In some embodiments, the electrical connector 38 may be used to transmit signals (e.g., digital signals) between the lower circuit pattern structure 2 and the upper circuit pattern structure 1. In some embodiments, the electrical connector 38 may include a re-flowable connector 382 and at least one core element 381 in the re-flowable connector 382. The re-flowable connector 382 may include a solder material such as SnAg alloy. The re-flowable connector 382 may be also referred to as “a re-flowable material” or “an outer material”, and may be disposed between and electrically connect the lower circuit pattern structure 2 and the upper circuit pattern structure 1. The at least one core element 381 may include one core element or a plurality of core elements attached to the re-flowable connector 382. The re-flowable connector 382 may be around the core element(s) 381. For example, the re-flowable connector 382 may encompass or enclose the core element(s) 381. Thus, the re-flowable connector 382 may accommodate or encapsulate the core element(s) 381.

The core element 381 may be in a ball shape such as a copper core ball. A melting point of the core element 381 may be higher than a melting point of the re-flowable connector 382. In some embodiments, the core element(s) 381 may include a conductive material, and an electrical conductivity of the conductive material of the core element(s) 381 is higher than an electrical conductivity of the re-flowable connector 382. An upper portion of the re-flowable connector 382 may be disposed in the first opening 131 of the bottommost dielectric layer 13 of the upper circuit pattern structure 1, so as to be electrically connected and physically connected to the first outer bond pad 141 of the upper circuit pattern structure 1. In addition, a lower portion of the re-flowable connector 382 may be disposed in the first opening 231 of the topmost dielectric layer 23 of the lower circuit pattern structure 2, so as to be electrically connected and physically connected to the second outer pad 241 of the lower circuit pattern structure 2.

In some embodiments, the at least one electrical connector 38 may include a plurality of electrical connectors 38 disposed around the electronic component 31. In some embodiments, the at least one electrical connector 38 may be a solid pillar.

The second thermal conductive structure 4 may be disposed between the upper circuit pattern structure 1 and the electronic component 31. The second thermal conductive structure 4 may include at least one wire 4. In some embodiments, the second thermal conductive structure 4 may include a plurality of wires 4. In some embodiments, the wires 4 may physically connect, electrically connect and/or thermally connect the upper circuit pattern structure 1 and the electronic component 31 and may be configured to conductive heat and/or transmit signals. Thus, the wires 4 may or may not have the function of transmitting signals (e.g., digital signals). The wires 4 may be configured to transfer heat between the electronic component 31 and the upper circuit pattern structure 1. For example, the wires 4 may be configured to dissipate heat from the electronic component 31 to the upper circuit pattern structure 1.

The wires 4 may be nanowires, and a width of each of the wires 4 may be less than 100 nm, and a length of each of the wires 4 may be greater than 3 μm, 5 μm or 10 μm. A material of the wire 4 may include copper (Cu), gold (Au), aluminum (Al), or other suitable metal material. The wires 4 may grow from the pads 3161 of the seed layer 316 of the electronic component 31 through a plating process. Upper ends of the wires 4 may connect to the first inner bond pad 142 of the bottommost circuit layer 14 of the upper circuit pattern structure 1 through metal-to-metal bonding. Thus, the wires 4 may physically connect and electrically connect the seed layer 316 on the backside surface 312 of the electronic component 31 and the first inner bond pad 142 of the upper circuit pattern structure 1.

The encapsulant 36 may be disposed between the upper circuit pattern structure 1 and the lower circuit pattern structure 2 to encapsulate the electronic component 31, the underfill 32, the at least one electrical connector 38 and the second thermal conductive structure 4 (e.g., the wires 4). A material of the encapsulant 36 may be a molding compound with or without fillers 363. A portion of the encapsulant 36 may be disposed between the wires 4. As shown in FIG. 2, the encapsulant 36 may include a plurality of fillers 363, and a region 39 occupied by the wires 4 is free of the fillers 363 between the wires 4. That is, the fillers 363 do not located in the space between the wires 4. There is no fillers 363 between the wires 4. The fillers 363 are located outside the region 39.

The capacitor 37 may be disposed under the electronic component 31, and may be electrically connected to the first surface 21 (e.g., the bottom surface) of the lower circuit pattern structure 2. The external connectors 35 (e.g., solder balls or solder bumps) are formed or disposed on the first surface 21 (e.g., the bottom surface) of the lower circuit pattern structure 2 for external connection.

Referring to FIG. 3, a first direction 61 may be defined as a direction between the seed layer 316 of the electronic component 31 and the first inner bond pad 142 of the upper circuit pattern structure 1. That is, the first direction 61 may be defined as a direction from the electronic component 31 (e.g., the first electronic component 31) to the upper circuit pattern structure 1 (e.g., the first thermal conductive structure 1). The first direction 61 may be an axial direction of the second thermal conductive structure 4 (e.g., the wire 4). For example, the first direction 61 may be from the seed layer 316 of the electronic component 31 to the first inner bond pad 142 of the upper circuit pattern structure 1, or from the first inner bond pad 142 of the upper circuit pattern structure 1 to the seed layer 316 of the electronic component 31. A second direction 62 may be defined as a direction nonparallel with the first direction 61 from the electronic component 31 to an element other than the upper circuit pattern structure 1 (e.g., the first thermal conductive structure 1). The second direction 62 may be perpendicular to the first direction 61. The second direction 62 may be from a center of the wire 4 to the encapsulant 36. The second direction 62 may be a radial direction of the wire 4. A length L of the wire 4 along the first direction 61 is greater than a width W of the wire 4 along the first direction 61. Since a heat transfer rate between the seed layer 316 of the electronic component 31 to the first inner bond pad 142 of the upper circuit pattern structure 1 is greater than a heat transfer rate between the wire 4 to the encapsulant 36, a first heat transfer rate of the second thermal conductive structure 4 (e.g., the wires 4) along the axial direction (i.e., the first direction 61) is greater than a second heat transfer rate of the second thermal conductive structure 4 (e.g., the wires 4) along the radial direction (i.e., the second direction 62). Therefore, the heat generated by the electronic component 31 will be dissipated from the seed layer 316 of the electronic component 31 to the first inner bond pad 142 of the upper circuit pattern structure 1 efficiently through the wires 4 along the axial direction (i.e., the first direction 61) because less heat will be dissipated along the radial direction (i.e., the second direction 62) of the wires 4. As a result, a heat dissipation efficiency of the electronic package structure 3 is improved.

In the embodiment illustrated in FIG. 1 to FIG. 3, two ends of the wires 4 may physically connect the seed layer 316 of the electronic component 31 and the first inner bond pad 142 of the upper circuit pattern structure 1 respectively. Thus, the wires 4 may be configured to inhibit (or reduce) a shift between the upper circuit pattern structure 1 and the electronic component 31. In addition, the wires 4 may be configured to inhibit (or reduce) a warpage of the upper circuit pattern structure 1.

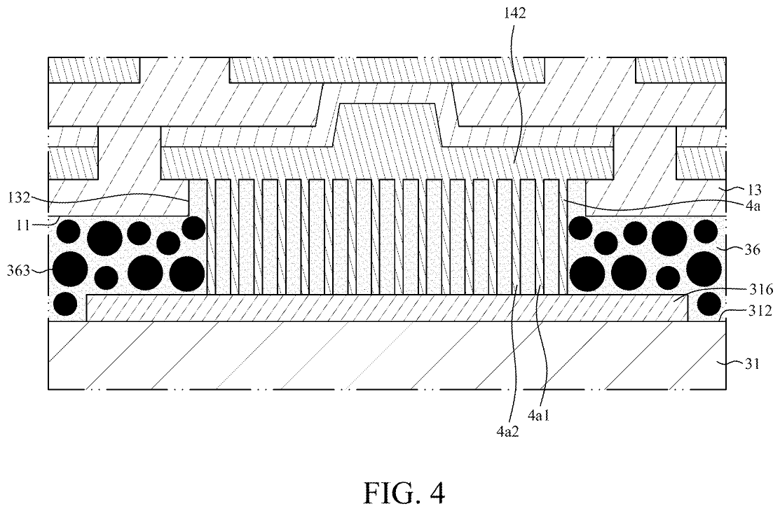

FIG. 4 illustrates a cross-sectional view of an example of a plurality of wires 4a according to some embodiments of the present disclosure. The wires 4a of FIG. 4 is similar to the wires 4 of FIG. 2, and the differences are described as follows. The upper ends of the wires 4a of FIG. 4 may be fused with the first inner bond pad 142 of the upper circuit pattern structure 1. Thus, there may be no obvious or visible interfaces between the upper ends of the wires 4a and the first inner bond pad 142 of the upper circuit pattern structure 1. In addition, the second thermal conductive structure 4a (e.g., the wires 4a) includes a first wire 4al and a second wire 4a2, there is no filler 363 between the first wire 4al and the second wire 42a.

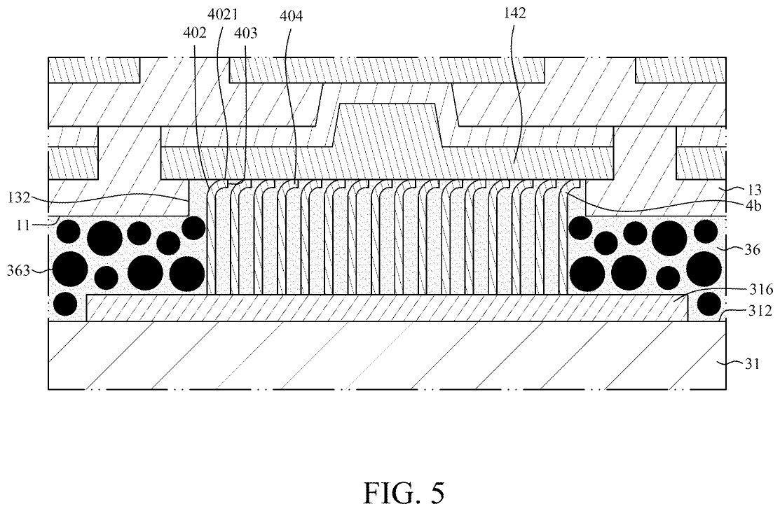

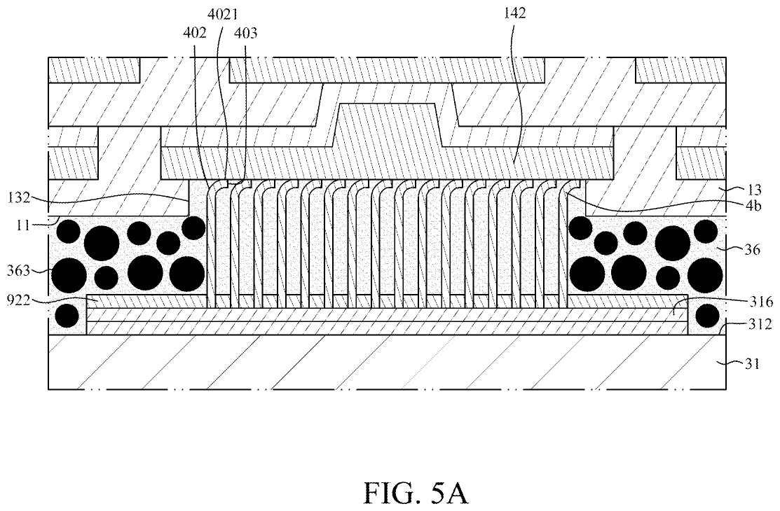

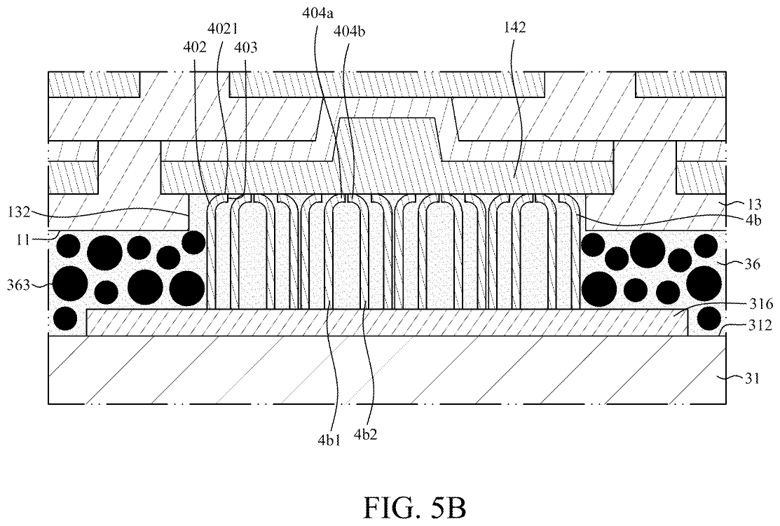

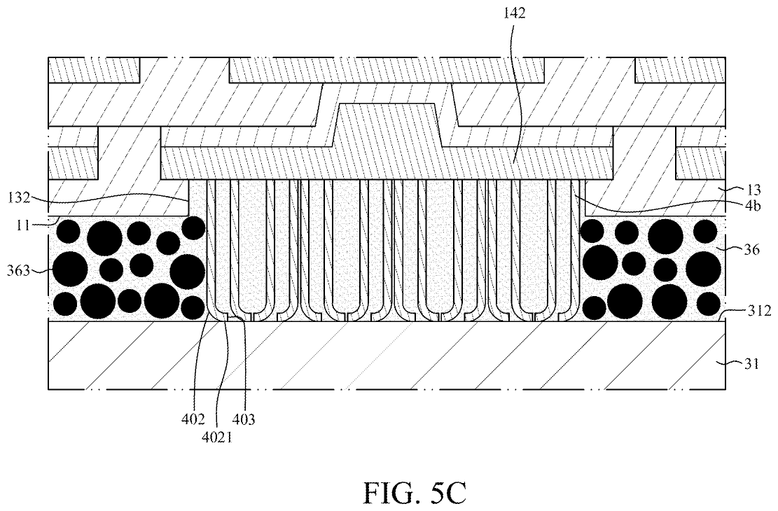

FIG. 5 illustrates a cross-sectional view of an example of a plurality of wires 4b according to some embodiments of the present disclosure. The wires 4b of FIG. 5 are similar to the wires 4 of FIG. 2, and the differences are described as follows. The wire 4b has a lateral surface 402 and an end surface 403 perpendicular to the lateral surface 402. The wire 4b may include at least one bended portion 404. The upper ends of the wires 4b of FIG. 5 may be curved and compressed by the first inner bond pad 142 of the upper circuit pattern structure 1 to form the bended portions 404. Thus, an upper portion of a lateral surface 402 (e.g., the lateral surface 402 of the bended portion 404) of the wire 4b is curved and connected to the first inner bond pad 142 of the upper circuit pattern structure 1. The bended portion 404 of the wire 4b may contact the first inner bond pad 142 of the upper circuit pattern structure 1. The lateral surface 402 of the wire 4b has a connection portion 4021 connecting to the first inner bond pad 142 of the upper circuit pattern structure 1. The connection portion 4021 may be an interface between the lateral surface 402 of the wire 4b and the first inner bond pad 142 of the upper circuit pattern structure 1. Further, the end surface 403 of the wire 4b may be substantially perpendicular to a surface of the first inner bond pad 142. In the embodiment illustrated in FIG. 5, the wires 4b may be configured to provide a buffer (or cushion) during a compression bonding process. The bended portion 404 of the wire 4 is close to the upper circuit pattern structure 1 (e.g., the first thermal conductive structure 1) and far away from the electronic component 31 (e.g., the first electronic component 31).

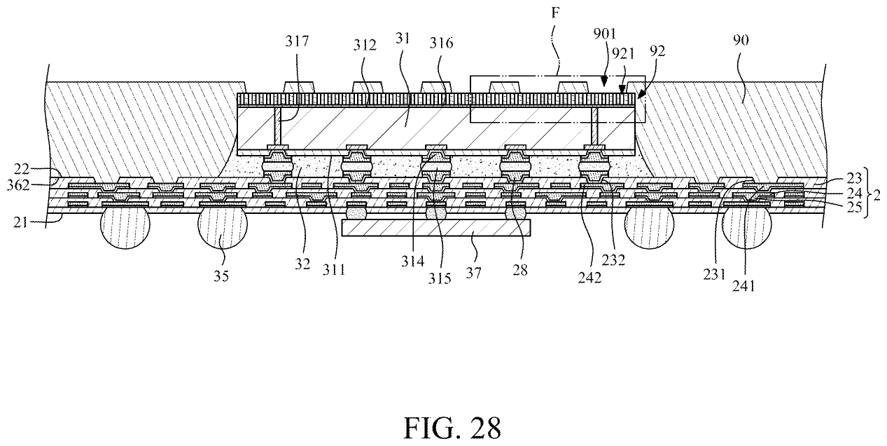

FIG. 5A illustrates a cross-sectional view of an example of a plurality of wires 4b according to some embodiments of the present disclosure. The structure of FIG. 5A is similar to the structure of FIG. 5, and the differences are described as follows. As shown in FIG. 5A, the seed layer 316 may include two layers. In addition, a portion 922 of a mold plate 92 (FIG. 28) may remain on the seed layer 316.

FIG. 5B illustrates a cross-sectional view of an example of a plurality of wires 4b according to some embodiments of the present disclosure. The wires 4b of FIG. 5B are similar to the wires 4b of FIG. 5, and the differences are described as follows. The wires 4b include a first wire 4b1 and a second wire 4b2. The first wire 4b1 includes a first bended portion 404a. The second wire 4b2 includes a second bended portion 404b. A bended direction of the first bended portion 404a is different from a bended direction of the second bended portion 404b. For example, the first bended portion 404a is toward the right side of FIG. 5B, and the second bended portion 404b is toward the left side of FIG. 5B. That is, all of the wires 4b may not be bended toward a same direction.

FIG. 5C illustrates a cross-sectional view of an example of a plurality of wires 4b according to some embodiments of the present disclosure. The structure of FIG. 5C is similar to the structure of FIG. 5, and the differences are described as follows. As shown in FIG. 5C, the seed layer 316 may be omitted. The wires 4b may extend from the first inner bond pad 142 of the upper circuit pattern structure 1. The bended portion of the wire 4b may contact the first electronic component 31. The lateral surface 402 of the wire 4b has a connection portion 4021 connecting to the first electronic component 31. The connection portion 4021 may be an interface between the lateral surface 402 of the wire 4b and the first electronic component 31.

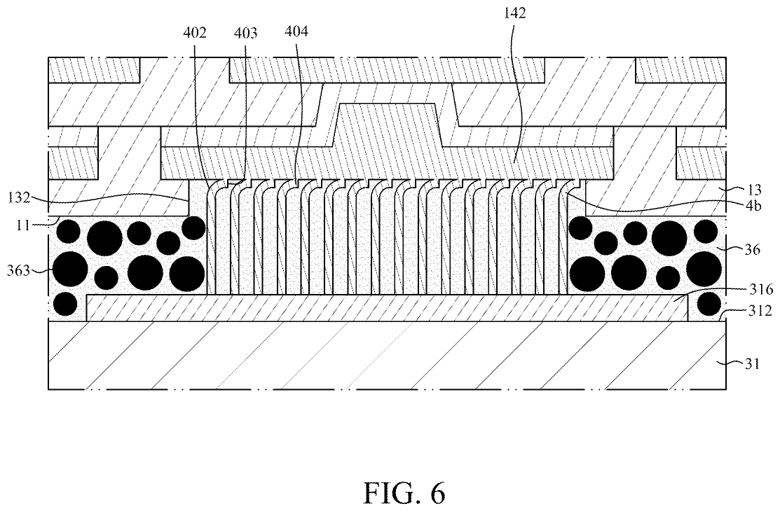

FIG. 6 illustrates a cross-sectional view of an example of a plurality of wires 4c according to some embodiments of the present disclosure. The wires 4c of FIG. 6 is similar to the wires 4b of FIG. 5, and the differences are described as follows. The upper portions of the wires 4c of FIG. 6 may be fused with the first inner bond pad 142 of the upper circuit pattern structure 1. Thus, there may be no interfaces between the upper portions of the wires 4c and the first inner bond pad 142 of the upper circuit pattern structure 1. That is, the connection portion 4021 of the lateral surface 402 of the wire 4c may be omitted. There is no obvious or visible interface between the bended portion 404 of the wire 4 and the first inner bond pad 142 of the upper circuit pattern structure 1 (e.g., the first thermal conductive structure 1) since the bended portion 404 of the wire 4 and the first inner bond pad 142 are fused together.

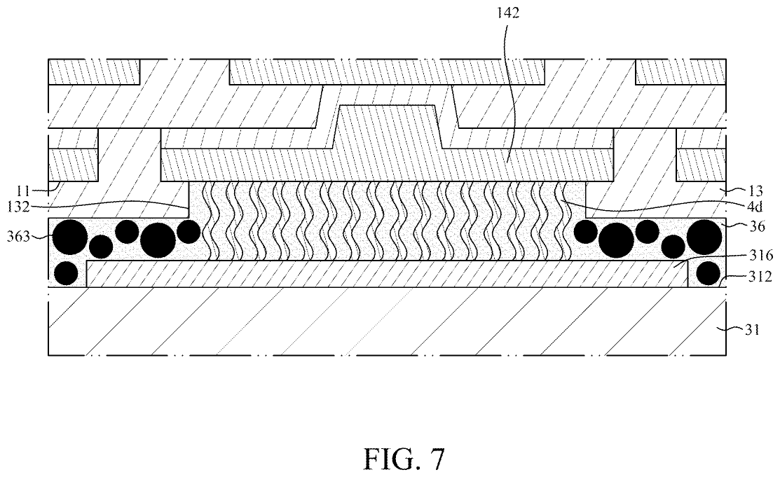

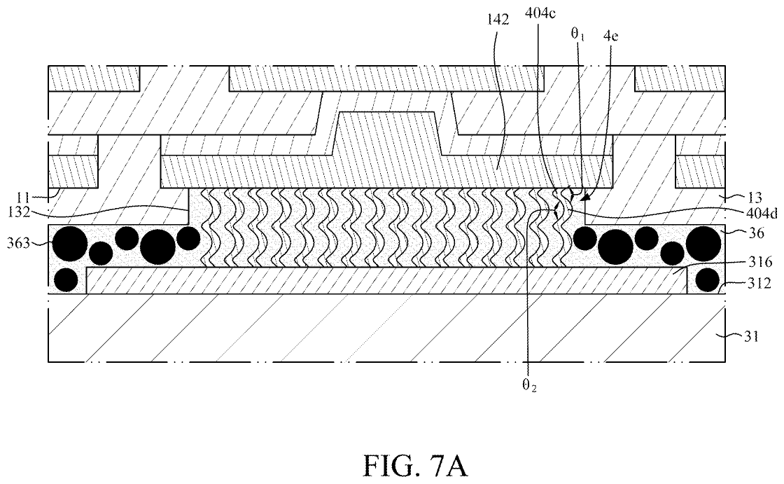

FIG. 7 illustrates a cross-sectional view of an example of a plurality of wires 4d according to some embodiments of the present disclosure. The wires 4d of FIG. 7 is similar to the wires 4 of FIG. 2, and the differences are described as follows. A gap between the seed layer 316 on the backside surface 312 of the electronic component 31 and the first inner bond pad 142 of the upper circuit pattern structure 1 is reduced. Thus, the wires 4d of FIG. 7 are compressed, and each of the wires 4d has an amount of deformation. The wires 4d of FIG. 7 may be bent to form a serpentine shape, S shape or irregular shape.

In the embodiment illustrated in FIG. 7, the wires 4d may be configured to provide a buffer (or cushion) during a compression bonding process. For example, the wires 4d may be configured to reduce (or absorb, sustain) the compression force (or impact force) on the electronic component 31 during the compression bonding process so as to protect the electronic component 31 from breaking during the compression bonding process. Since the wires 4d are in solid state and are flexible during the compression bonding process, the wires 4d may convert the compression force into elastic potential energy during the compression bonding process.

FIG. 7A illustrates a cross-sectional view of an example of a plurality of wires 4e according to some embodiments of the present disclosure. The wires 4e of FIG. 7A is similar to the wires 4d of FIG. 7, and the differences are described as follows. The wire 4e includes a first bended portion 404c and a second bended portion 404d. The first bended portion 404c has a first included angle θ1 and a first curvature. The second bended portion 404d has a second included angle θ2 and a second curvature. The first included angle θ1 is different from the second included angle θ2. The first curvature is different from the second curvature.

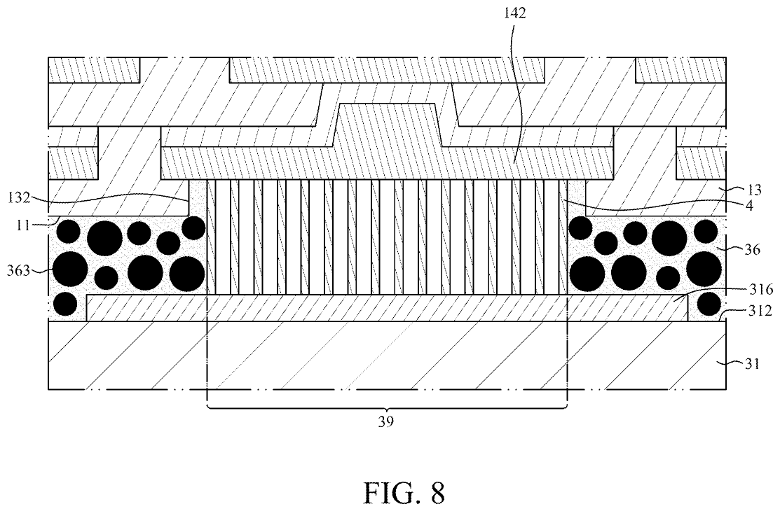

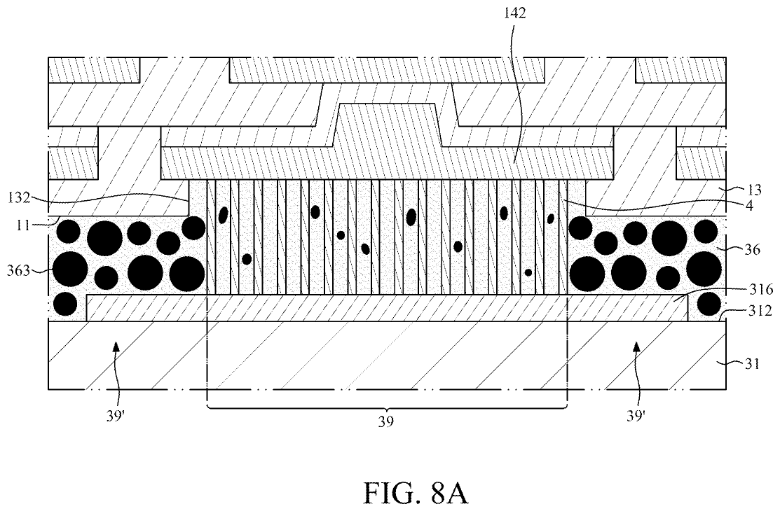

FIG. 8 illustrates a structure of an enlarged view of an area of a cross-sectional view of an electronic package structure according to some embodiments of the present disclosure. The structure of FIG. 8 is similar to the structure of FIG. 2, and the differences are described as follows. As shown in FIG. 8, a region 39 occupied by the wires 4 is free of the encapsulant 36. That is, the encapsulant 36 does not extend to the space between the wires 4. There is no encapsulant 36 between the wires 4.

FIG. 8A illustrates a structure of an enlarged view of an area of a cross-sectional view of an electronic package structure according to some embodiments of the present disclosure. The structure of FIG. 8A is similar to the structure of FIG. 2, and the differences are described as follows. As shown in FIG. 8A, a first amount of the fillers 363 in a first region 39 occupied by the wires 4 is less than a second amount of the fillers 363 in a second region 39′ outside the first region 39. That is, there is more fillers 363 in the first region 39 than in the second region 39′.

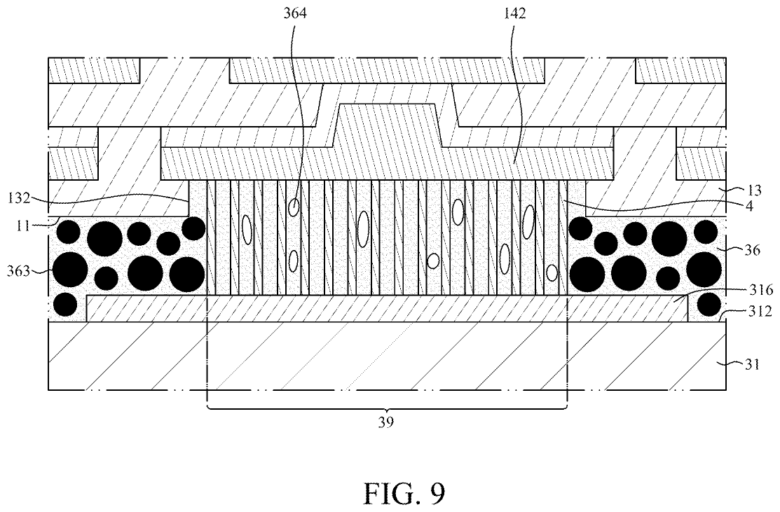

FIG. 9 illustrates a structure of an enlarged view of an area of a cross-sectional view of an electronic package structure according to some embodiments of the present disclosure. The structure of FIG. 9 is similar to the structure of FIG. 2, and the differences are described as follows. As shown in FIG. 9, the encapsulant 36 in a region 39 occupied by the wires 4 defines at least one void 364 between the wires 4. That is, the encapsulant 36 does not completely fill the space between the wires 4 in the region 39.

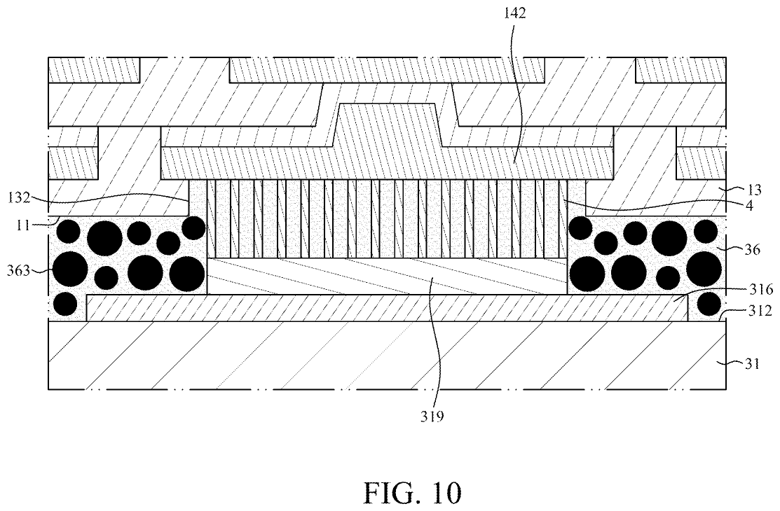

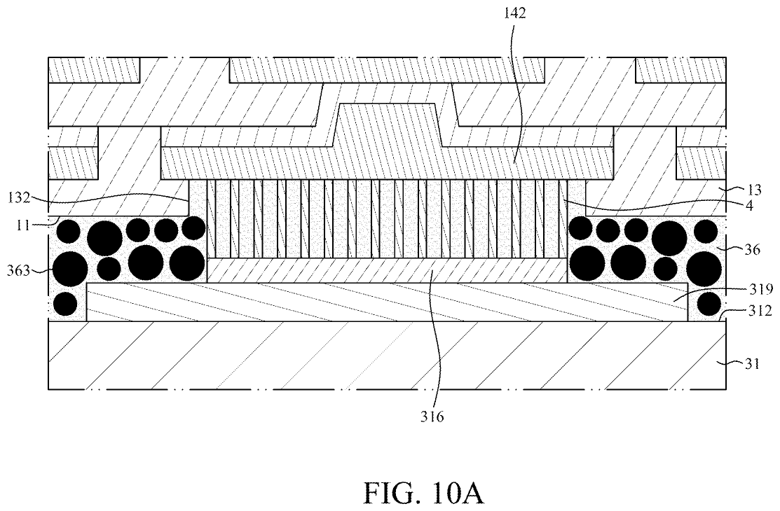

FIG. 10 illustrates a structure of an enlarged view of an area of a cross-sectional view of an electronic package structure according to some embodiments of the present disclosure. The structure of FIG. 10 is similar to the structure of FIG. 2, and the differences are described as follows. As shown in FIG. 10, a booster pad 319 may be disposed between the wires 4 and the seed layer 316 on the backside surface 312 of the electronic component 31. The booster pad 319 may be a metal layer or metal bulk formed or disposed on the seed layer 316. The wires 4 may be formed on the booster pad 319. Thus, the required length of the wires 4 may be reduced. A length of the wire 4 of FIG. 10 may be less than a length of the wire 4 of FIG. 2. In some embodiments, when a length of the wire 4 is less than a gap between the seed layer 316 of the electronic component 31 and the first inner bond pad 142 of the upper circuit pattern structure 1, a thickness of the booster pad 319 may compensate the difference between the length of the wire 4 and the gap between the seed layer 316 of the electronic component 31 and the first inner bond pad 142 of the upper circuit pattern structure 1. The booster pad 319 may be configured to make the wires 4 close to the upper circuit pattern structure 1 (e.g., the first thermal conductive structure 1). The booster pad 319 may be configured to reduce a distance between the wires 4 and the upper circuit pattern structure 1 (e.g., the first thermal conductive structure 1). The booster pad 319 may be configured to increase an amount of the wires 4 that contact the upper circuit pattern structure 1 (e.g., the first thermal conductive structure 1).

FIG. 10A illustrates a structure of an enlarged view of an area of a cross-sectional view of an electronic package structure according to some embodiments of the present disclosure. The structure of FIG. 10A is similar to the structure of FIG. 10, and the differences are described as follows. As shown in FIG. 10A, the booster pad 319 may be disposed between the seed layer 316 and the backside surface 312 of the electronic component 31.

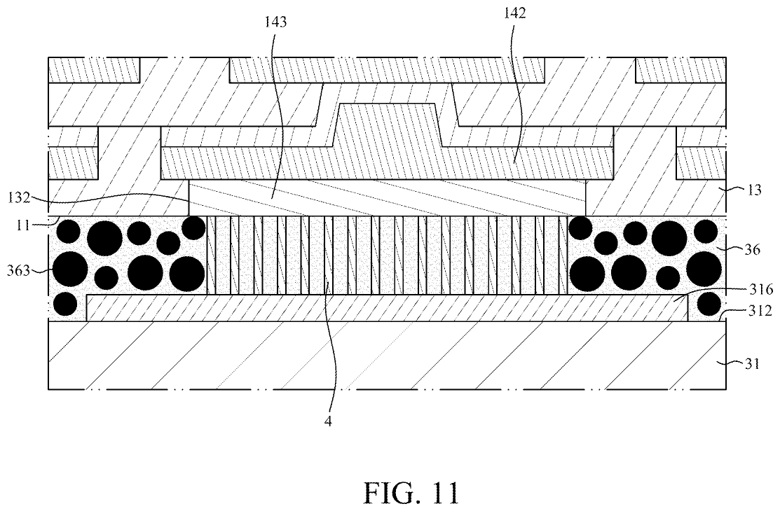

FIG. 11 illustrates a structure of an enlarged view of an area of a cross-sectional view of an electronic package structure according to some embodiments of the present disclosure. The structure of FIG. 11 is similar to the structure of FIG. 2, and the differences are described as follows. As shown in FIG. 11, a conductive material 143 may be disposed between the wires 4 and the first inner bond pad 142 of the upper circuit pattern structure 1. The conductive material 143 may be a metal layer or metal bulk formed or disposed on the first inner bond pad 142 of the upper circuit pattern structure 1. The upper portions of the wires 4 may connect to the booster pad 319. Thus, the required length of the wires 4 may be reduced. A length of the wire 4 of FIG. 11 may be less than a length of the wire 4 of FIG. 2. In some embodiments, when a length of the wire 4 is less than a gap between the seed layer 316 of the electronic component 31 and the first inner bond pad 142 of the upper circuit pattern structure 1, a thickness of the conductive material 143 may compensate the difference between the length of the wire 4 and the gap between the seed layer 316 of the electronic component 31 and the first inner bond pad 142 of the upper circuit pattern structure 1. In some embodiments, the conductive material 143 may fill the second opening 132 of the bottommost dielectric layer 13.

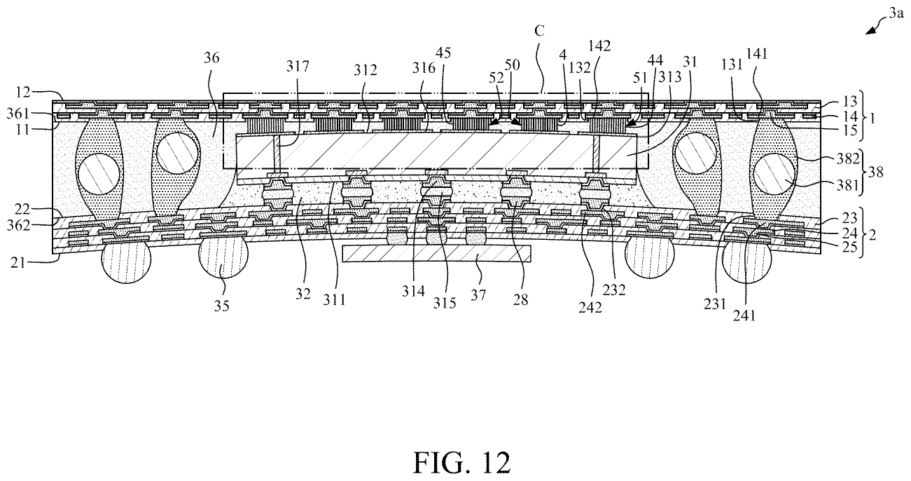

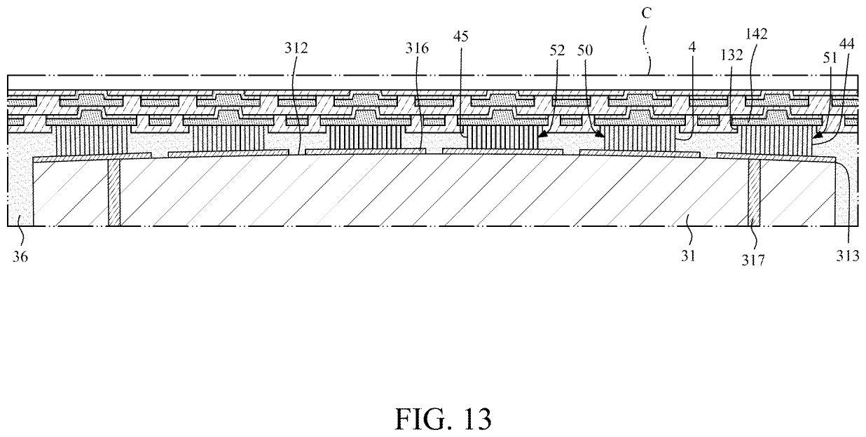

FIG. 12 illustrates a cross-sectional view of an electronic package structure 3a according to some embodiments of the present disclosure. FIG. 13 illustrates an enlarged view of an area “C” of FIG. 12. The electronic package structure 3a of FIG. 12 is similar to the electronic package structure 3 of FIG. 1, except that the lower circuit pattern structure 2 and/or the electronic component 31 has a warpage. As shown in FIG. 12, the lower circuit pattern structure 2 and/or the electronic component 31 is convex toward the upper circuit pattern structure 1. Thus, the gap 50 between the electronic component 31 and the upper circuit pattern structure 1 gradually increases toward a periphery edge 313 of the electronic component 31. For example, the gap 50 includes a first gap 51 and a second gap 52 both are between the electronic component 31 and the upper circuit pattern structure 1. The first gap 51 is closer to the periphery edge 313 of the electronic component 31 than the second gap 52 is. A height of the first gap 51 is greater than a height of the second gap 52.

The wires 4 include at least one first wire 44 and at least one second wire 45 both are disposed between the electronic component 31 and the upper circuit pattern structure 1. The first wire 44 is located in the first gap 51, and the second wire 45 is located in the second gap 52. A length or a height of the first wire 44 is greater than a length or a height of the second wire 45. That is, the length or the height of the first wire 44 is different from the length or the height of the second wire 45. The first wire 44 is closer to the periphery edge 313 of the electronic component 31 than the second wire 45 is.

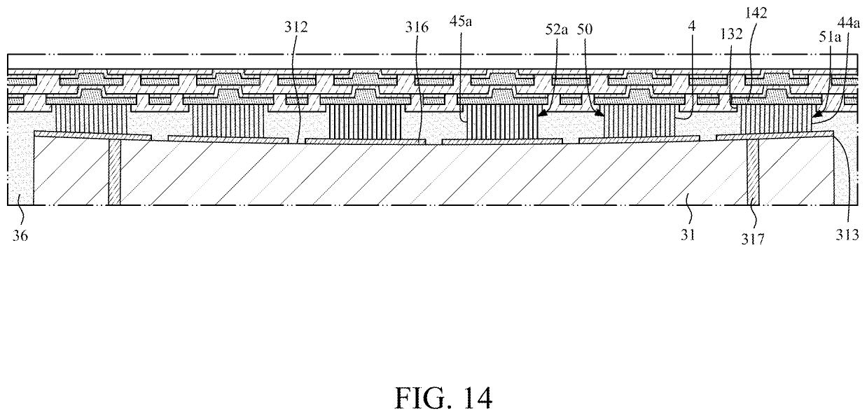

FIG. 14 illustrates a structure of an enlarged view of an area of a cross-sectional view of an electronic package structure according to some embodiments of the present disclosure. The structure of FIG. 14 is similar to the structure of FIG. 13, and the differences are described as follows. The lower circuit pattern structure 2 and/or the electronic component 31 has a warpage. As shown in FIG. 14, the lower circuit pattern structure 2 and/or the electronic component 31 is concave toward the upper circuit pattern structure 1. Thus, the gap 50 between the electronic component 31 and the upper circuit pattern structure 1 gradually decreases toward the periphery edge 313 of the electronic component 31. For example, the gap 50 includes a first gap 51a and a second gap 52a both are between the electronic component 31 and the upper circuit pattern structure 1. The first gap 51a is closer to the periphery edge 313 of the electronic component 31 than the second gap 52a is. A height of the first gap 51a is less than a height of the second gap 52a.

The wires 4 include at least one first wire 44a and at least one second wire 45a both are disposed between the electronic component 31 and the upper circuit pattern structure 1. The first wire 44a is located in the first gap 51a, and the second wire 45a is located in the second gap 52a. A length or a height of the first wire 44a is less than a length or a height of the second wire 45a. That is, the length or the height of the first wire 44a is different from the length or the height of the second wire 45a. The first wire 44a is closer to the periphery edge 313 of the electronic component 31 than the second wire 45a is.

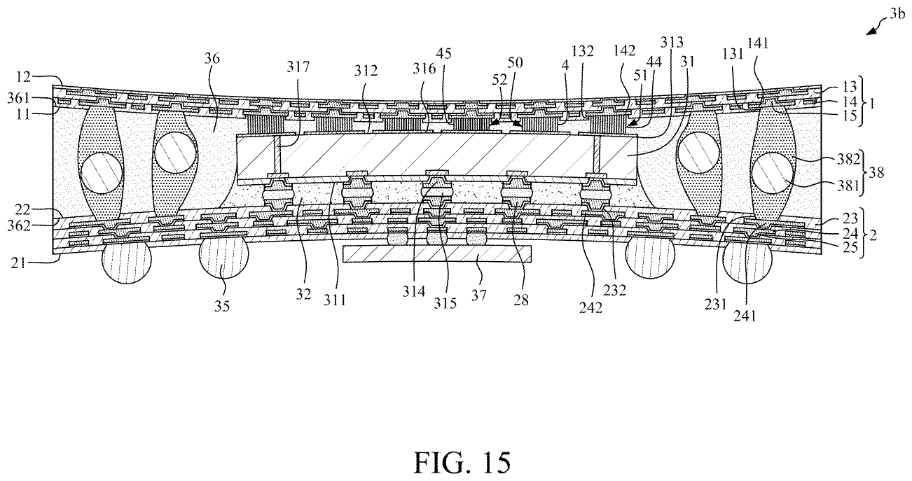

FIG. 15 illustrates a cross-sectional view of an electronic package structure 3b according to some embodiments of the present disclosure. The electronic package structure 3b of FIG. 15 is similar to the electronic package structure 3a of FIG. 12, except that the upper circuit pattern structure 1 has a warpage. As shown in FIG. 15, the upper circuit pattern structure 1 is convex toward the lower circuit pattern structure 2.

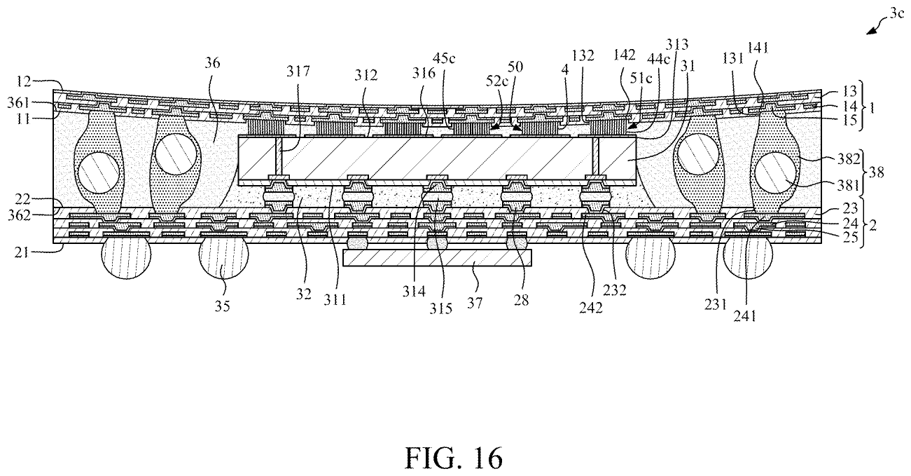

FIG. 16 illustrates a cross-sectional view of an electronic package structure 3c according to some embodiments of the present disclosure. The electronic package structure 3c of FIG. 16 is similar to the electronic package structure 3 of FIG. 1, except that the upper circuit pattern structure 1 has a warpage. As shown in FIG. 16, the upper circuit pattern structure 1 is convex toward the lower circuit pattern structure 2. Thus, the gap 50 between the electronic component 31 and the upper circuit pattern structure 1 gradually increases toward the periphery edge 313 of the electronic component 31. For example, the gap 50 includes a first gap 51c (e.g., a first portion 51c) and a second gap 52c (e.g., a second portion 52c) both are between the electronic component 31 and the upper circuit pattern structure 1. The first gap 51c is closer to the periphery edge 313 of the electronic component 31 than the second gap 52c is. A height of the first gap 51c is greater than a height of the second gap 52c.

The wires 4 include at least one first wire 44c and at least one second wire 45c both are disposed between the electronic component 31 and the upper circuit pattern structure 1. The first wire 44c is located in the first gap 51c, and the second wire 45c is located in the second gap 52c. A length or a height of the first wire 44c is greater than a length or a height of the second wire 45c. The first wire 44c is closer to the periphery edge 313 of the electronic component 31 than the second wire 45c is.

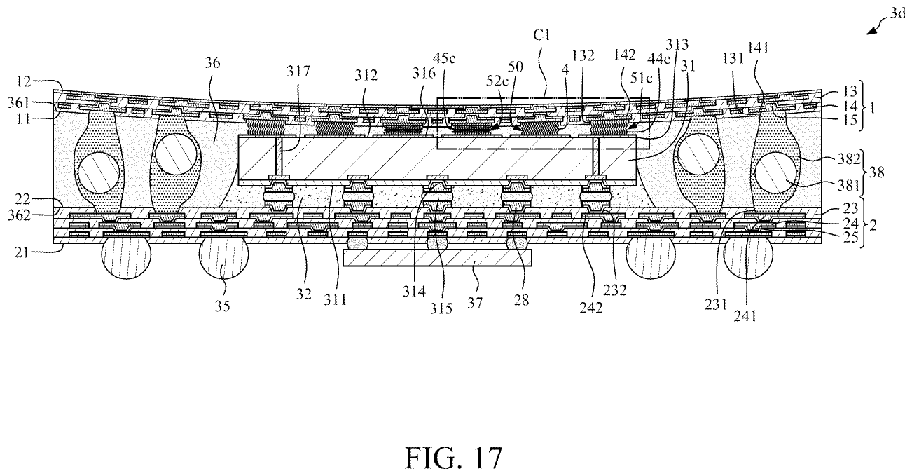

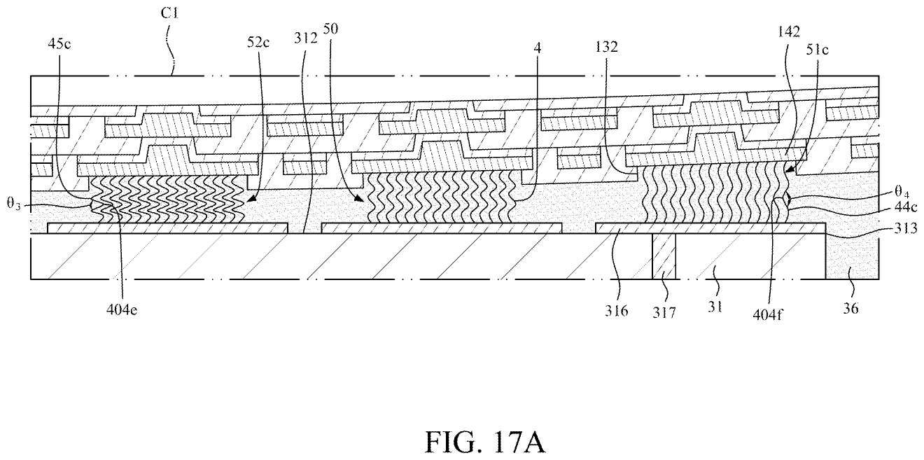

FIG. 17 illustrates a cross-sectional view of an electronic package structure 3d according to some embodiments of the present disclosure. FIG. 17A illustrates an enlarged view of an area “C1” of FIG. 17. The electronic package structure 3d of FIG. 17 is similar to the electronic package structure 3c of FIG. 16, except that the wires 4 are compressed and deform. As shown in FIG. 17, an amount of deformation of the first wire 44c is less than an amount of deformation of the second wire 45c. It is noted that an original length (i.e., a length in an uncompressed state) of the first wire 44c is substantially equal to an original length of the second wire 45c. In some embodiments, the lower circuit pattern structure 2 may be also referred to as “a first circuit pattern structure 2.” The upper circuit pattern structure 1 may be also referred to as “a second circuit pattern structure 1.” The electronic component 31 is disposed over the first circuit pattern structure 2. The second circuit pattern structure 1 is disposed over the electronic component 31. The gap 50 is between the second circuit pattern structure 1 and the electronic component 31. The gap 50 includes a first portion 52c and a second portion 51c. The wires 4 are disposed in the first portion 52c and the second portion 51c. A height of the first portion 52c is different from a height of the second portion 51c. The wires 4 are disposed in the gap 50. The wires 4 are configured to maintain a spacing between the second circuit pattern structure 1 and the electronic component 31 when the second circuit pattern structure 1 is bonded to the first circuit pattern structure 2 due to the spring of the wires 4.

Referring to FIG. 17A, the height of the first portion 52c is less than the height of the second portion 51c. The wires 4 include a first wire 45c and a second wire 44c. The first wire 45c is disposed in the first portion 52c and has a bended portion 404e with a first included angle θ3. The second wire 44c is disposed in the second portion 51c and has a bended portion 404f with a second included angle θ4. The first included angle θ3 is less than the second included angle θ4.

Referring to FIG. 17, the electrical connector 38 may be also referred to as “a re-flowable contactor 38.” The electronic package structure 3d may include a plurality of re-flowable contactors 38 disposed between the first circuit pattern structure 2 and the second circuit pattern structure 1. The wires 4 support the second circuit pattern structure 1, and are configured to inhibit the second circuit pattern structure 1 from moving toward the first circuit pattern structure 2 so as to prevent a bridge between adjacent two of the re-flowable contactors 38.

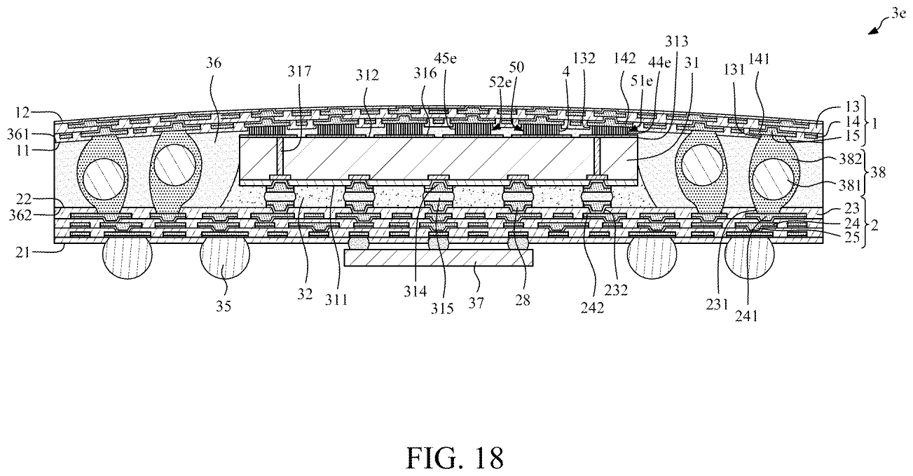

FIG. 18 illustrates a cross-sectional view of an electronic package structure 3e according to some embodiments of the present disclosure. The electronic package structure 3e of FIG. 18 is similar to the electronic package structure 3 of FIG. 1, except that the upper circuit pattern structure 1 has a warpage. As shown in FIG. 18, the upper circuit pattern structure 1 is concave toward the lower circuit pattern structure 2. Thus, the gap 50 between the electronic component 31 and the upper circuit pattern structure 1 gradually decreases toward the periphery edge 313 of the electronic component 31. For example, the gap 50 includes a first gap 51e and a second gap 52e both are between the electronic component 31 and the upper circuit pattern structure 1. The first gap 51e is closer to the periphery edge 313 of the electronic component 31 than the second gap 52e is. A height of the first gap 51e is less than a height of the second gap 52e.

The wires 4 include at least one first wire 44e and at least one second wire 45e both are disposed between the electronic component 31 and the upper circuit pattern structure 1. The first wire 44e is located in the first gap 51e, and the second wire 45e is located in the second gap 52e. A length or a height of the first wire 44e is less than a length or a height of the second wire 45e. The first wire 44e is closer to the periphery edge 313 of the electronic component 31 than the second wire 45e is.

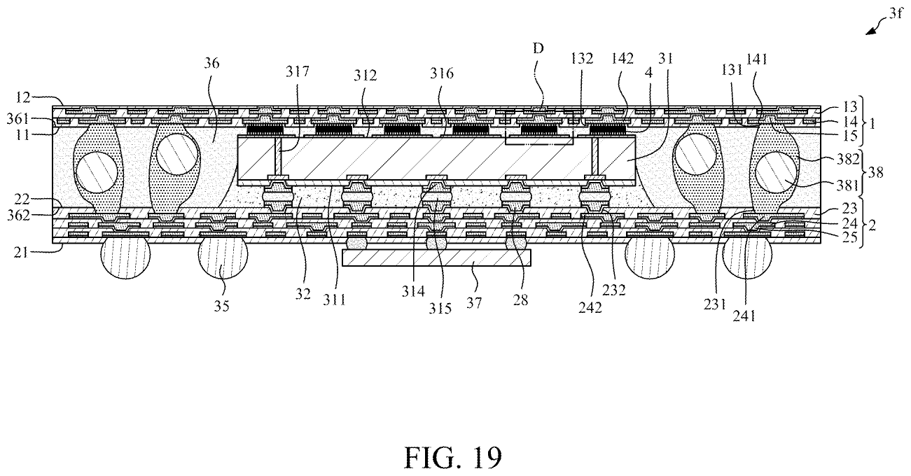

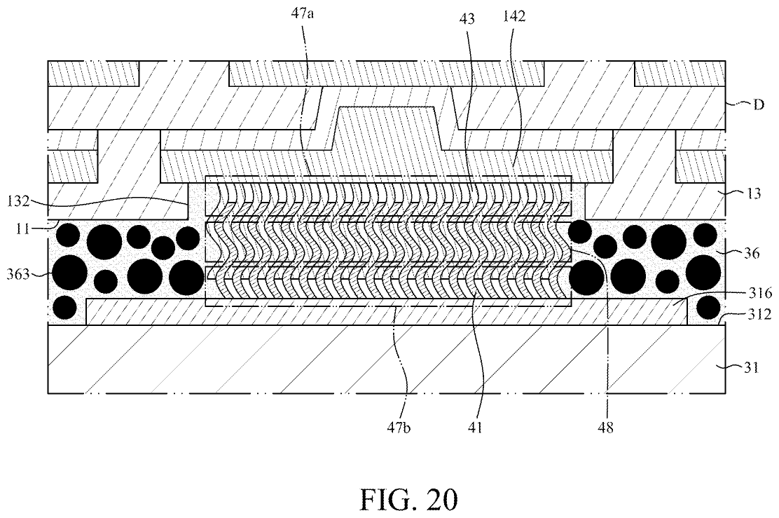

FIG. 19 illustrates a cross-sectional view of an electronic package structure 3f according to some embodiments of the present disclosure. FIG. 20 illustrates an enlarged view of an area “D” of FIG. 19. The electronic package structure 3f of FIG. 19 is similar to the electronic package structure 3 of FIG. 1, and the differences are described as follows.

The wires 4 include a plurality of first wires 41 and a plurality of third wires 43. The first wires 41 protrude or grow from the seed layer 316 of the electronic component 31. The third wires 43 protrude or grow from the first inner bond pad 142 of the upper circuit pattern structure 1. The first wires 41 are inserted into the gap between the third wires 43, and the third wires 43 are inserted into the gap between the first wires 41. Thus, the first wires 41 and the third wires 43 are entangled with each other. Thus, the first wires 41 and the third wires 43 are joined tightly through the clamping force therebetween. Therefore, the combination of the first wires 41 and the third wires 43 may be configured to inhibit (or reduce) a shift between the upper circuit pattern structure 1 and the electronic component 31. In addition, the combination of the first wires 41 and the third wires 43 may be configured to inhibit (or reduce) a warpage of the upper circuit pattern structure 1. In some embodiments, the first wires 41 may not contact the first inner bond pad 142 of the upper circuit pattern structure 1, and the third wires 43 may not contact the seed layer 316 of the electronic component 31.

In some embodiments, the lower circuit pattern structure 2 may be also referred to as “a first circuit pattern structure 2.” The second outer pad 241 may be also referred to as “a first pad 241.” The upper circuit pattern structure 1 may be also referred to as “a second circuit pattern structure 1.” The first outer bond pad 141 may be also referred to as “a second pad 141.”

The electronic component 31 is disposed over the first circuit pattern structure 2. The second circuit pattern structure 1 is disposed over the electronic component 31. The second pad 141 faces the first pad 241. The re-flowable contactors 38 are disposed between and electrically connecting the first pad 241 of the first circuit pattern structure 2 and the second pad 141 of the second circuit pattern structure 1. A fixing structure 4 (e.g., the wires 4) is disposed between the electronic component 31 and the second circuit pattern structure 1, and is configured to inhibit a shift between the first pad 241 and the second pad 141 during a reflow process.

Referring to FIG. 20, the fixing structure 4 (e.g., the wires 4) include a first wire 41 and a second wire 43. The first wire 41 connects to the electronic component 31 and extends toward the second circuit pattern structure 1. The second wire 43 connects to the second circuit pattern structure 1 and extends toward the electronic component 31. The first wire 41 directly contacts the second wire 43. The wires 4 form a high-density wire distribution region 48 and two low-density wire distribution regions 47a, 47b. An amount of the wires 4 in the high-density wire distribution region 48 is greater than an amount the wires 4 in the low-density wire distribution region 47a, 47b. The low-density wire distribution region 47b is closer to the electronic component 31 than the high-density wire distribution 48 region is. The low-density wire distribution region 47a is closer to the second circuit pattern structure 1 than the high-density wire distribution region 48 is. The high-density wire distribution region 48 is located between the two low-density wire distribution regions 47a, 47b.

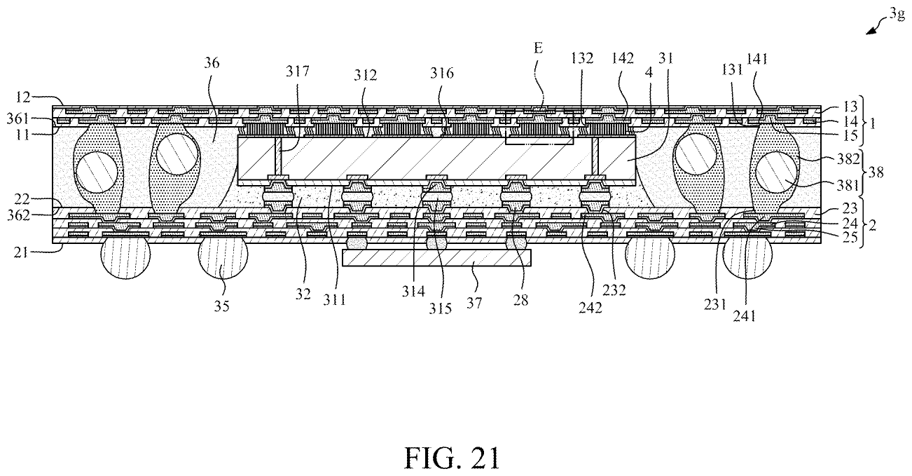

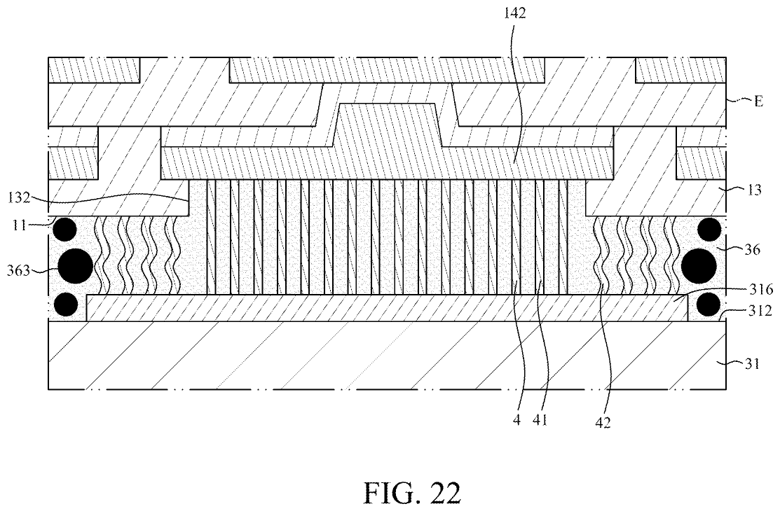

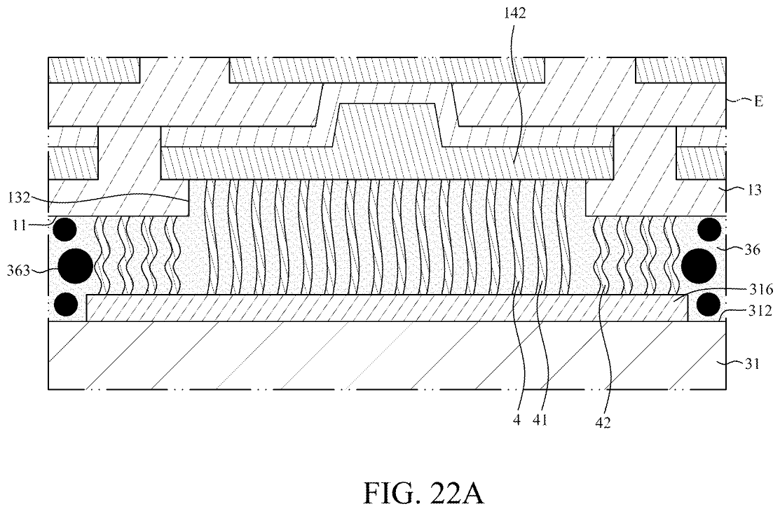

FIG. 21 illustrates a cross-sectional view of an electronic package structure 3g according to some embodiments of the present disclosure. FIG. 22 illustrates an enlarged view of an area “E” of FIG. 21. The electronic package structure 3g of FIG. 21 is similar to the electronic package structure 3 of FIG. 1, and the differences are described as follows.

The wires 4 include a plurality of first wires 41 and a plurality of second wires 42 protruding or growing from the seed layer 316 of the electronic component 31. The upper portions of the first wires 41 may be connected to the first inner bond pad 142 of the upper circuit pattern structure 1, and may be configured to conduct heat and/or transmit signals. The upper portions of the second wires 42 may contact the dielectric layer 13 (or protection layer) of the upper circuit pattern structure 1. The second wires 42 may be configured to provide a buffer (or cushion) during a compression bonding process.

In some embodiments, an original length (or uncompressed length) of the first wire 41 may be greater than or substantially equal to an original length (or uncompressed length) of the second wire 42. An amount of deformation of the second wire 42 is greater than an amount of deformation of the first wire 41.

FIG. 22A illustrates a structure of an enlarged view of an area of a cross-sectional view of an electronic package structure according to some embodiments of the present disclosure. The structure of FIG. 22A is similar to the structure of FIG. 22, and the differences are described as follows. As shown in FIG. 22A, the first wires 41 are also bended.

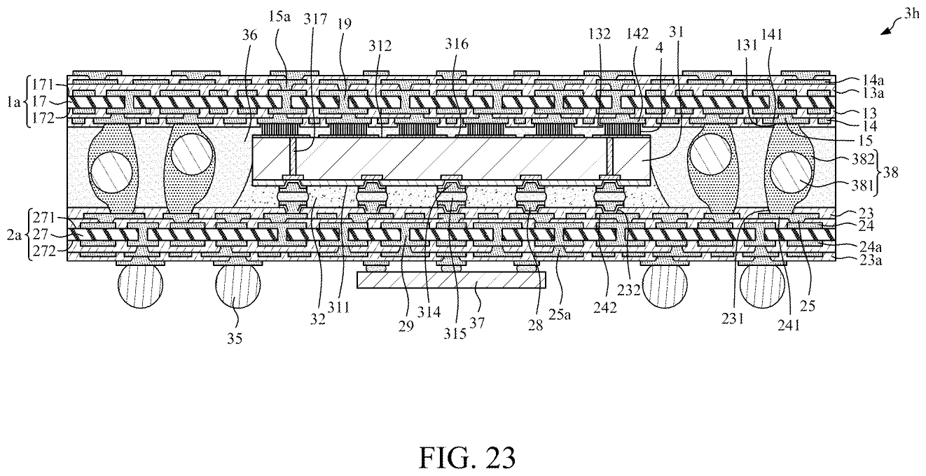

FIG. 23 illustrates a cross-sectional view of an electronic package structure 3h according to some embodiments of the present disclosure. The electronic package structure 3h of FIG. 23 is similar to the electronic package structure 3 of FIG. 1, and the differences are described as follows. The upper circuit pattern structure 1a of FIG. 23 is a substrate structure. The upper circuit pattern structure 1a includes a plurality of dielectric layers 13, 13a, a plurality of circuit layers 14, 14a in contact with the dielectric layers 13, 13a and a plurality of inner vias 15, 15a. In some embodiments, the upper circuit pattern structure 1a may be similar to a core substrate that further includes a core portion 17. A plurality of interconnection vias 19 may extend through the core portion 17 for vertical connection. The dielectric layers 13a are disposed on the top surface 171 of the core portion 17. The dielectric layers 13 are disposed on the bottom surface 172 of the core portion 17. In some embodiments, the circuit layers 14a are formed or disposed on the top surface 171 of the core portion 17, covered by the dielectric layers 13a, and electrically connected to each other through the inner vias 15a. The circuit layers 14 are formed or disposed on the bottom surface 172 of the core portion 17, covered by the dielectric layers 13, and electrically connected to each other through the inner vias 15.

The lower circuit pattern structure 2a includes a plurality of dielectric layers 23, 23a, a plurality of circuit layers 24, 24a in contact with the dielectric layers 23, 23a and a plurality of inner vias 25, 25a. In some embodiments, the lower circuit pattern structure 2a may be similar to a core substrate that further includes a core portion 27. A plurality of interconnection vias 29 may extend through the core portion 27 for vertical connection. The dielectric layers 23 are disposed on the top surface 271 of the core portion 27. The dielectric layers 23a are disposed on the bottom surface 272 of the core portion 27. In some embodiments, the circuit layers 24 are formed or disposed on the top surface 271 of the core portion 27, covered by the dielectric layers 23, and electrically connected to each other through the inner vias 25. The circuit layers 24a are formed or disposed on the bottom surface 272 of the core portion 27, covered by the dielectric layers 23, and electrically connected to each other through the inner vias 25a.

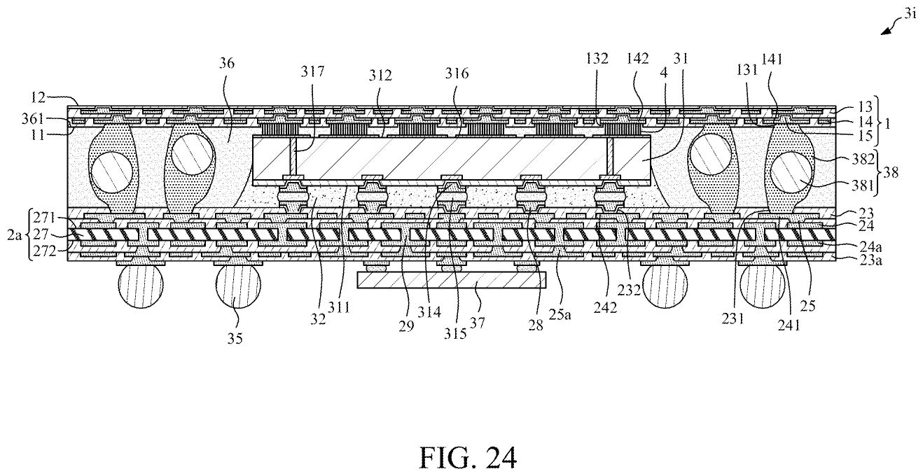

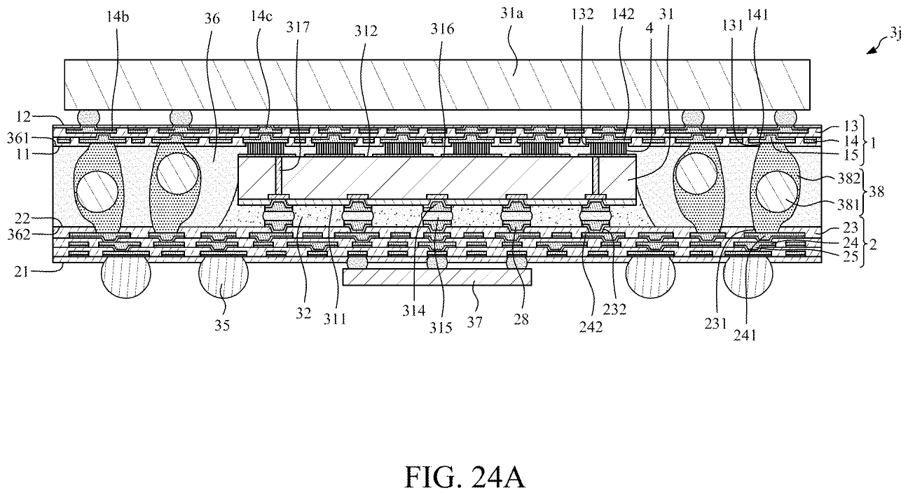

FIG. 24 illustrates a cross-sectional view of an electronic package structure 3i according to some embodiments of the present disclosure. The electronic package structure 3i of FIG. 24 is similar to the electronic package structure 1 of FIG. 1, except that the lower circuit pattern structure 2a of FIG. 24 is a substrate structure similar to or same as the lower circuit pattern structure 2a of FIG. 23.

FIG. 24A illustrates a cross-sectional view of an electronic package structure 3j according to some embodiments of the present disclosure. The electronic package structure 3j of FIG. 24A is similar to the electronic package structure 1 of FIG. 1, except that a second electronic component 31a may be included. The second electronic component 31a is disposed over the upper circuit pattern structure 1 (e.g., the first thermal conductive structure 1). The upper circuit pattern structure 1 (e.g., the first thermal conductive structure 1) may include at least one patterned circuit layer such as a first patterned circuit layer 14b and a second patterned circuit layer 14c. The second electronic component 31a is electrically connected to the first electronic component 31 through the first patterned circuit layer 14b, the electrical connector 38, and the lower circuit pattern structure 2. The second patterned circuit layer 14c is thermally connected to the first electronic component 31 through the second thermal conductive structure 4 (e.g., the wires 4). The second patterned circuit layer 14c is configured to guide a heat from the second thermal conductive structure 4 (e.g., the wires 4) to outside the electronic package structure 3j.

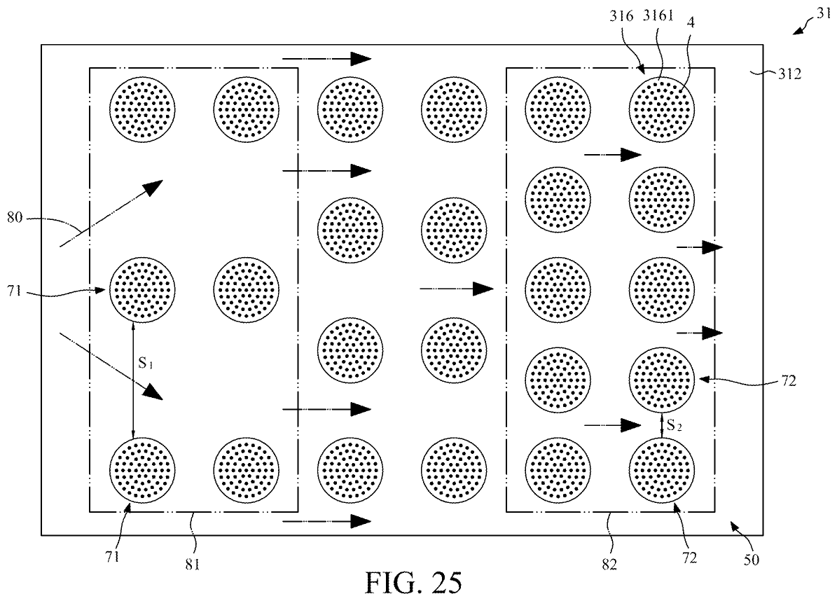

FIG. 25 illustrates an example of a top view of the electronic component 31 of FIG. 1. The wires 4 include a plurality of groups of wires. For example, the wires 4 include one or more first groups 72 of wires and one or more second groups 71 of wires disposed on a respective one of the pads 3161 of the seed layer 316. The gap 50 between the electronic component 31 and the upper circuit pattern structure 1 may include a first area 82 and a second area 81 different from the first area 82. The first groups 72 of wires are disposed on the first area 82, and the second groups 71 are disposed on the second area 81. The spacing between the plurality of groups of wires may be inconsistent. For example, a spacing S¹ between the second groups 71 of wires may be greater than a spacing S₂ between the first groups 72 of wires. The second group 71 is spaced apart from the first group 72. In a top view, a layout of the first group 72 is geometrically distinct from a layout of the second group 71. The first area 82 may be a high density region, and the second area 81 may be a low density region. That is, a first distribution density of the wires 4 in the first area 82 is different from a second distribution density of the wires 4 in the second area 81. For example, the first distribution density of the wires 4 in the first area 82 may be greater than the second distribution density of the wires 4 in the second area 81. During a molding process, a speed of mold flow 80 of the encapsulant 36 in the second region 81 may be greater than a speed of mold flow 80 of the encapsulant 36 in the first region 82.

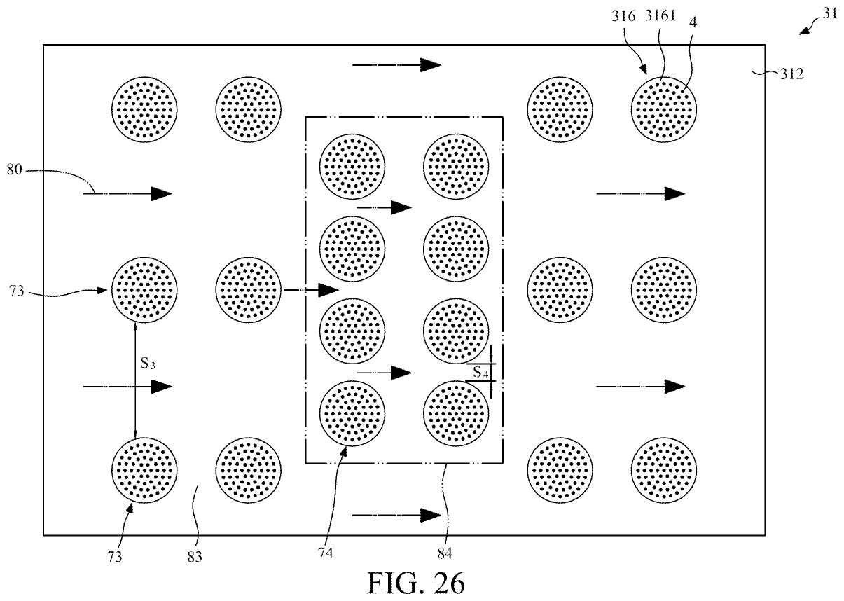

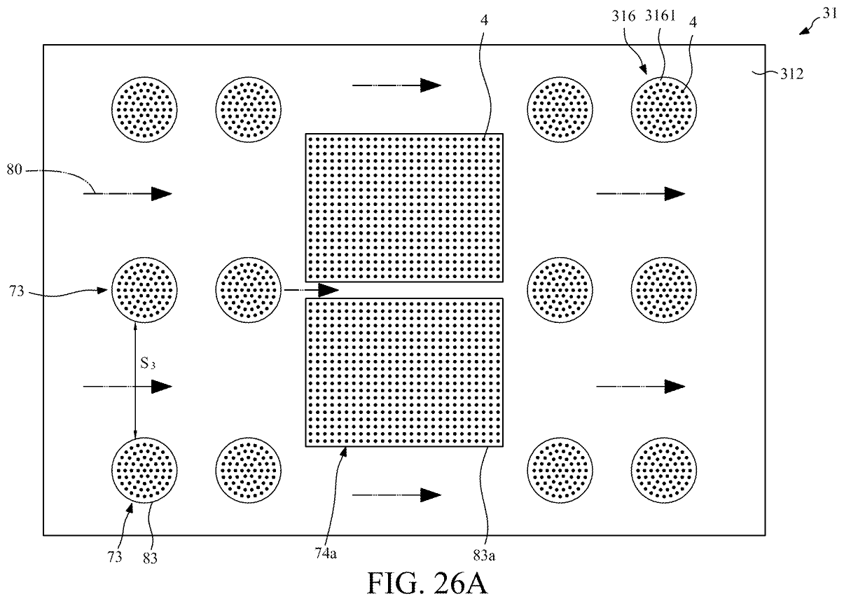

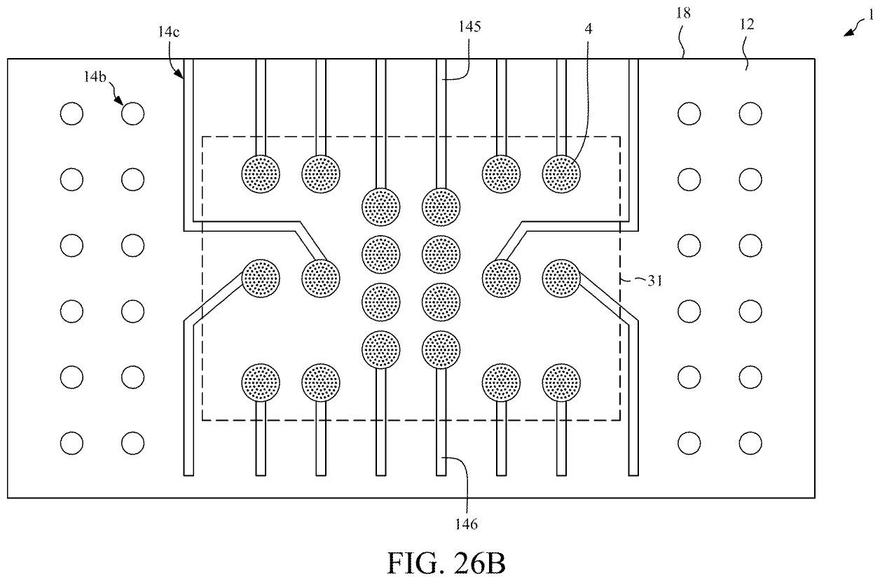

FIG. 26 illustrates an example of a top view of the electronic component 31 of FIG. 1. The wires 4 include a plurality of groups of wires. For example, the wires 4 include one or more first groups 73 of wires and one or more second groups 74 of wires disposed on a respective one of the pads 3161 of the seed layer 316. The backside surface 312 of the electronic component 31 has a first region 83 and a second region 84. The first groups 73 of wires are disposed in the first region 83, and the second groups 74 of wires are disposed in the second region 84. The spacing between the plurality of groups of wires may be inconsistent. For example, a spacing S₃ between the first groups 73 of wires may be greater than a spacing S₄ between the second groups 74 of wires. Thus, the first region 83 may be a low density region, and the second region 84 may be a high density region. During a molding process, a speed of mold flow 80 of the encapsulant 36 in the first region 83 may be greater than a speed of mold flow 80 of the encapsulant 36 in the second region 84. As shown in FIG. 26, the second region 84 may be a hot spot region according a simulation of heat distribution. The second region 84 may be at the center of the backside surface 312 of the electronic component 31, and the first region 83 may surround the second region 84.

FIG. 26A illustrates an example of a top view of the electronic component 31 of FIG. 1. The wires 4 include a plurality of groups of wires. For example, the wires 4 include one or more first groups 73 of wires and one or more second groups 74a of wires disposed on a respective one of the pads 3161 of the seed layer 316. The backside surface 312 of the electronic component 31 has at least one first area 83 (or a pad 3161 of the seed layer 316) and at least one second area 83a (or a pad 3161 of the seed layer 316). The first groups 73 of wires occupy the first area 83, and the second groups 74a of wires 4 occupy the second area 83a. The first area 83 and the second area 83a are spaced apart from each other. The first area 83 and the second area 83a have different shapes and/or sizes. That is, the wires 4 include a plurality of groups 73, 74a of wires occupying a plurality of areas 83, 83a spaced apart from each other, and the area s 83, 83a have different shapes and/or sizes. In other words, the second group 74a is spaced apart from the first group 73. In a top view, a layout of the first group 73 is geometrically distinct from a layout of the second group 74a. In the top view, the first area 83 defined by the layout of the first group 73 is different from the second area 83a defined by the layout of second group 74a.

FIG. 26B illustrates an example of a top view of the electronic package structure 3j of FIG. 24A, wherein the second electronic component 31a is omitted. The second patterned circuit layer 14c may include a first thermal trace 145 and a second thermal trace 146. The first thermal trace 145 may be thermally connected to the second thermal conductive structure 4 (e.g., the wires 4) and may extend to an edge 18 of the upper circuit pattern structure 1 (e.g., the first thermal conductive structure 1). Thus, a portion of the first thermal trace 145 may be exposed from the edge 18 of the upper circuit pattern structure 1 (e.g., the first thermal conductive structure 1). The second thermal trace 146 may be thermally connected to the second thermal conductive structure 4 (e.g., the wires 4) and may not extend to the edge 18 of the upper circuit pattern structure 1 (e.g., the first thermal conductive structure 1). Thus, the second thermal trace 146 may not be exposed from the edge 18 of the upper circuit pattern structure 1 (e.g., the first thermal conductive structure 1).

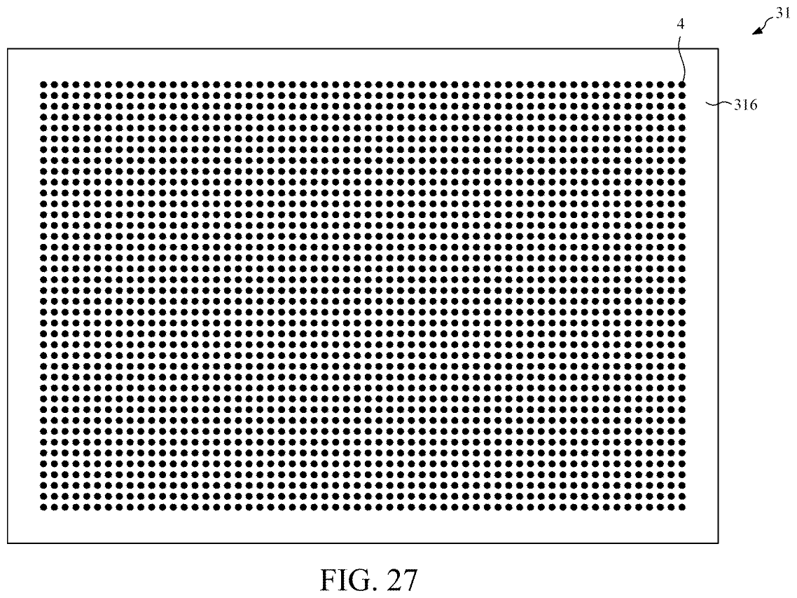

FIG. 27 illustrates an example of a top view of the electronic component 31 of FIG. 1. The seed layer 316 may be disposed on the entire backside surface 312 of the electronic component 31 completely. That is, the seed layer 316 may be not patterned. The wires 4 may be disposed on the seed layer 316 completely, for example, in an array arrangement.

FIG. 28 through FIG. 34 illustrate a method for manufacturing an electronic package structure according to some embodiments of the present disclosure. In some embodiments, the method is for manufacturing the electronic package structure 3 shown in FIG. 1.

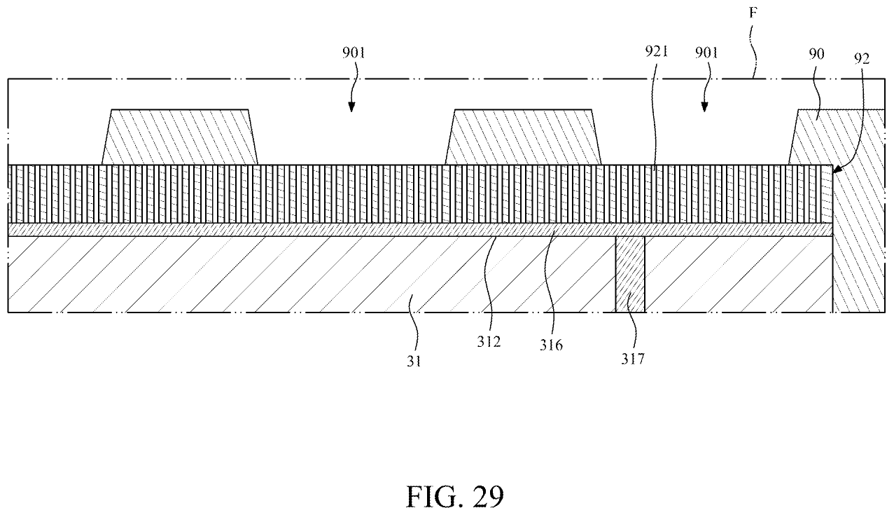

Referring to FIG. 28 an FIG. 29, wherein FIG. 29 illustrates an enlarged view of an area “F” of FIG. 28, an electronic component 31 is bonded to a lower circuit pattern structure 2, and electrically connected to the circuit layer 24 of the lower circuit pattern structure 2 through the solder materials 315 and the electrical contacts 314. The electronic component 31 and the lower circuit pattern structure 2 of FIG. 28 may be similar to or same as the electronic component 31 and the lower circuit pattern structure 2 of FIG. 1, respectively.

Then, a mold plate 92 is provided or disposed on the seed layer 316 on the backside surface 312 of the electronic component 31. The mold plate 92 defines a plurality of through hole 921 extending the mold plate 92. For example, the mold plate 92 may be a porous anodic aluminum oxide (AAO) template. Then, a solder mask 90 may be formed or disposed to cover the lower circuit pattern structure 2 and the mold plate 92. The solder mask 90 defines a plurality of openings 901 to expose some through holes 921 of the mold plate 92.

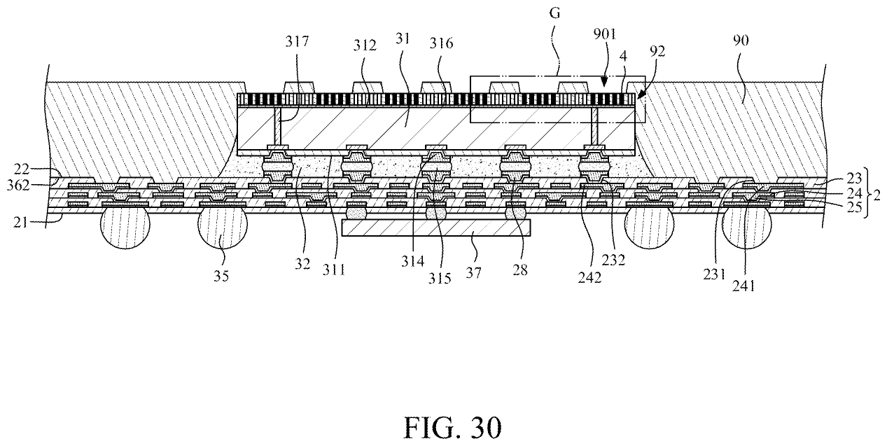

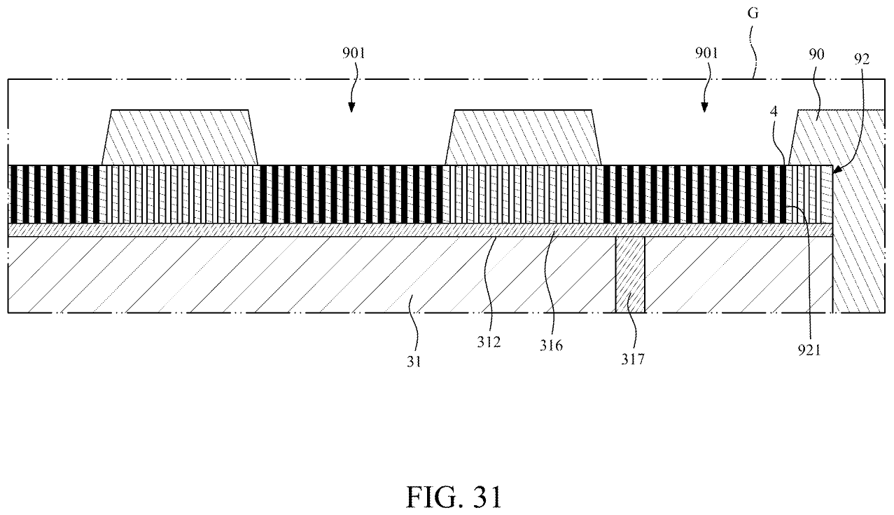

Referring to FIG. 30 an FIG. 31, wherein FIG. 31 illustrates an enlarged view of an area “G” of FIG. 30, a conductive material is formed in the exposed through holes 921 of the mold plate 92 by, for example, plating, so as to form a plurality of wires 4 in the exposed through holes 921 on the seed layer 316.

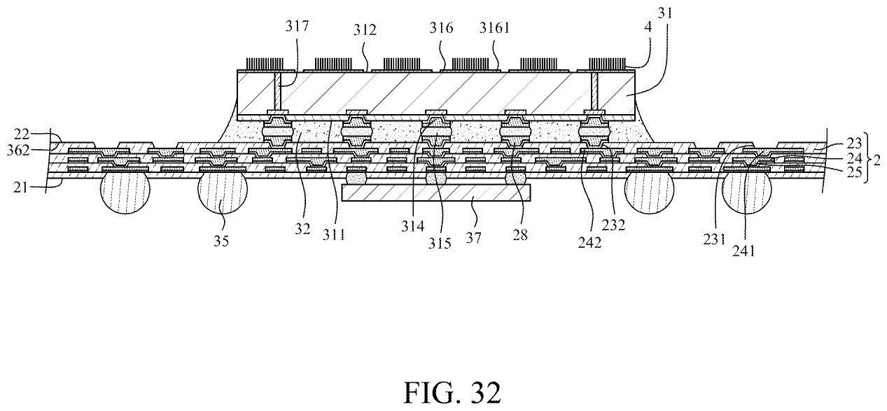

Referring to FIG. 32, the solder mask 90 and the mold plate 92 are removed. In some embodiments, the seed layer 316 may be patterned to form a plurality of pads 3161.

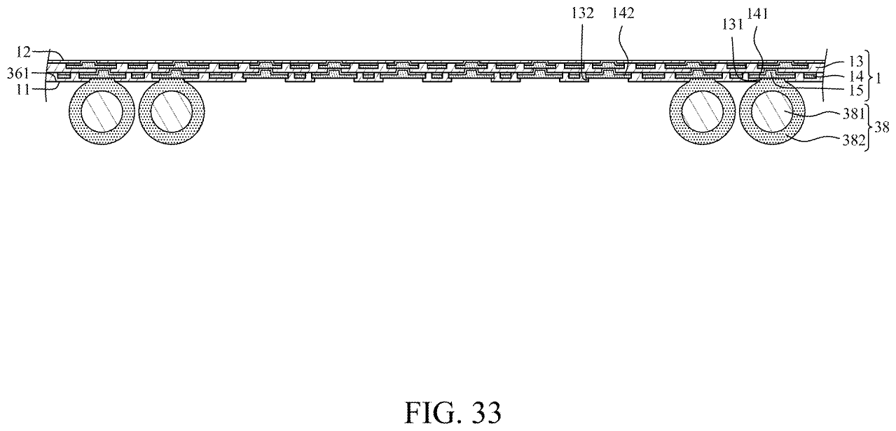

Referring to FIG. 33, an upper circuit pattern structure 1 is provided. Then, a plurality of electrical connectors 38 (e.g., coated core elements) are provided or disposed on the first surface 11 of the upper circuit pattern structure 1. The upper circuit pattern structure 1 and the electrical connector s38 of FIG. 33 may be similar to or same as the upper circuit pattern structure 1 and the electrical connectors 38 of FIG. 1, respectively.

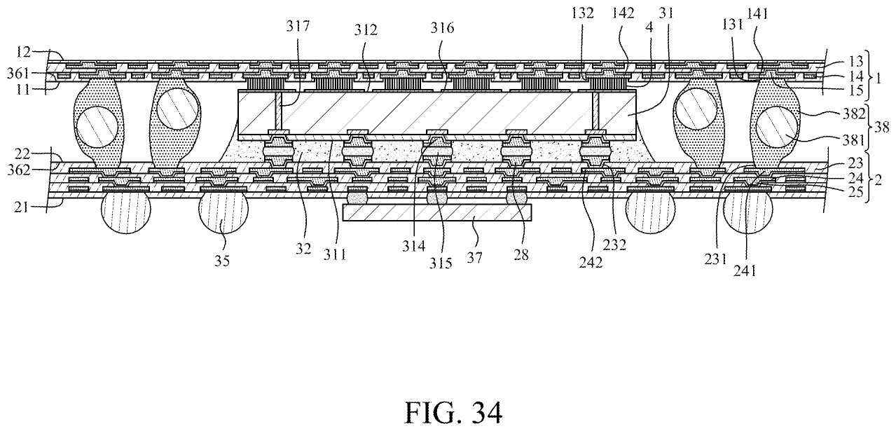

Referring to FIG. 34, the upper circuit pattern structure 1 and the electrical connectors 38 are attached to the lower circuit pattern structure 2 through a thermal compression bonding. Meanwhile, the lower portion of the re-flowable connector 382 of the electrical connector 38 may be melted to be electrically connected and physically connected to the second outer pad 241 of the lower circuit pattern structure 2. The upper portions of the wires 4 may be connected to the first inner bond pad 142 of the upper circuit pattern structure 1.

Then, an encapsulant 36 may be formed or disposed between the upper circuit pattern structure 1 and the lower circuit pattern structure 2 to encapsulate the electronic component 31, the underfill 32, the wires 4 and the electrical connector 38.

Then, a singulation process is conducted to obtain a plurality of electronic package structures 3 of FIG. 1.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electronic package structure, comprising:
a first electronic component;
a first thermal conductive structure disposed over the first electronic component; and
a second thermal conductive structure disposed between the first electronic component and the first thermal conductive structure, wherein a first heat transfer rate of the second thermal conductive structure along a first direction from the first electronic component to the first thermal conductive structure is greater than a second heat transfer rate of the second thermal conductive structure along a second direction nonparallel with the first direction from the first electronic component to an element other than the first thermal conductive structure.

2. The electronic package structure of claim 1, wherein the second thermal conductive structure includes at least one wire, a length of the at least one wire along the first direction is greater than a width of the at least one wire along the first direction.

3. The electronic package structure of claim 1, wherein the second thermal conductive structure includes at least one wire, the at least one wire includes at least one bended portion.

4. The electronic package structure of claim 3, wherein the at least one bended portion of the at least one wire is close to the first thermal conductive structure and far away from the first electronic component.

5. The electronic package structure of claim 1, wherein the second thermal conductive structure includes a plurality of wires, the electronic package structure further comprises an encapsulant encapsulating the first electronic component and the second thermal conductive structure, and a portion of the encapsulant is disposed between the wires.

6. The electronic package structure of claim 5, wherein the plurality of wires include a first wire and a second wire, the first wire includes a first bended portion, the second wire includes a second bended portion, and a bended direction of the first bended portion is different from a bended direction of the second bended portion.

7. The electronic package structure of claim 5, further comprising a booster pad disposed between the plurality of wires and the first electronic component.

8. The electronic package structure of claim 5, wherein the encapsulant includes a plurality of fillers, and a first amount of the plurality of fillers in a first region occupied by the plurality of wires is less than a second amount of the plurality of fillers in a second region outside the first region.

9. The electronic package structure of claim 5, wherein the encapsulant includes a plurality of fillers, the second thermal conductive structure includes a first wire and a second wire, and there is no filler between the first wire and the second wire.

10. The electronic package structure of claim 1, wherein the first thermal conductive structure includes at least one patterned circuit layer.

11. The electronic package structure of claim 10, further comprising a second electronic component disposed over the first thermal conductive structure.

12. The electronic package structure of claim 11, wherein the at least one patterned circuit layer includes a first patterned circuit layer and a second patterned circuit layer, wherein the second electronic component is electrically connected to the first electronic component through the first patterned circuit layer, and the second patterned circuit layer is thermally connected to the first electronic component through the second thermal conductive structure.

13. An electronic package structure, comprising:
a first circuit pattern structure;
an electronic component disposed over the first circuit pattern structure;
a second circuit pattern structure disposed over the electronic component, wherein a gap is between the second circuit pattern structure 1a and the electronic component, the gap includes a first portion and a second portion, a height of the first portion is different from a height of the second portion; and
a plurality of wires disposed in the first portion and the second portion.

14. The electronic package structure of claim 13, wherein the height of the first portion is less than the height of the second portion, the wires include a first wire and a second wire, the first wire is disposed in the first portion and has a bended portion with a first included angle, the second wire is disposed in the second portion and has a bended portion with a second included angle, wherein the first included angle is less than the second included angle.

15. The electronic package structure of claim 13, further comprising a plurality of re-flowable contactors disposed between the first circuit pattern structure and the second circuit pattern structure, wherein the plurality of wires support the second circuit pattern structure and are configured to inhibit the second circuit pattern structure from moving toward the first circuit pattern structure.

16. The electronic package structure of claim 13, wherein in a top view, the gap includes a first area and a second area different from the first area, a first distribution density of the plurality of wires in the first area is different from a second distribution density of the plurality of wires in the second area.

17. The electronic package structure of claim 13, wherein the plurality of wires include a first group and a second group spaced apart from the first group, and wherein, in a top view, a layout of the first group is geometrically distinct from a layout of the second group.

18. The electronic package structure of claim 17, wherein in the top view, a first area defined by the layout of the first group is different from a second area defined by the layout of second group.

19. An electronic package structure, comprising:
a first circuit pattern structure including a first pad;
an electronic component disposed over the first circuit pattern structure;
a second circuit pattern structure disposed over the electronic component, and including a second pad facing the first pad;
a re-flowable contactors disposed between and electrically connecting the first pad of the first circuit pattern structure and the second pad of the second circuit pattern structure; and
a fixing structure disposed between the electronic component and the second circuit pattern structure, and configured to inhibit a shift between the second pad and the first pad during a reflow process.

20. The electronic package structure of claim 19, wherein the fixing structure include a plurality of wires comprising a high-density wire distribution region and a low-density wire distribution region, wherein the low-density wire distribution region is closer to the electronic component or the second circuit pattern structure than the high-density wire distribution region is.
